(19) United States
(12) Patent Application Publication
(10) Pub. No.: US 2026/0267055 A1
(43) Pub. Date: Sep. 10, 2026

(54) Gradient Coating Apparatus

(71) Applicant: Envisics Ltd, Milton Keynes (GB)

(72) Inventor: Yiren Xia, Milton Keynes (GB)

(21) Appl. No.: 19/292,083

(22) Filed: Aug. 6, 2025

(30) Foreign Application Priority Data
Mar. 4, 2025 (GB) 2503109.7

(51) Int. Cl. F21V 8/00; C23C 14/04; C23C 14/35; C23C 14/50; C23C 14/56

(52) U.S. Cl. CPC G02B 6/0065; C23C 14/044; C23C 14/35; C23C 14/50; C23C 14/56

(57) ABSTRACT

The disclosure provides methods of coating pluralities of waveguides for head-up display by providing certain groupings and arrangements of the waveguides in various opposing orientations, and coating a first group of waveguides and a second group of waveguides through a shadow mask comprising a stacked array of hexagonal apertures comprising a series of alternating first sections having decreasing aperture width and second sections having increasing aperture width, wherein the first sections are aligned with odd-numbered rows of waveguides and the second sections are aligned with even-numbered rows of waveguides.

### CROSS-REFERENCE TO RELATED APPLICATIONS

This application claims the benefit of priority of United Kingdom Patent Application no. 2503109.7, filed Mar. 4, 2025, which is hereby incorporated herein by reference in its entirety.

### FIELD

The present disclosure relates to a device for applying a coating and a method of coating. More specifically, the present disclosure relates to a coating device and a method of coating a plurality of samples. Yet more specifically, the present disclosure relates to a coating device arranged to provide a gradient of coating thickness and a method of providing a gradient of coating thickness. The present disclosure also relates to the particular geometry of a shadow mask and its alignment with a plurality of sample positions on a sample carrier.

### BACKGROUND AND INTRODUCTION

Light scattered from an object contains both amplitude and phase information. This amplitude and phase information can be captured on, for example, a photosensitive plate by well-known interference techniques to form a holographic recording, or “hologram”, comprising interference fringes. The hologram may be reconstructed by illumination with suitable light to form a two-dimensional or three-dimensional holographic reconstruction, or replay image, representative of the original object.

Computer-generated holography may numerically simulate the interference process. A computer-generated hologram may be calculated by a technique based on a mathematical transformation such as a Fresnel or Fourier transform. These types of holograms may be referred to as Fresnel/Fourier transform holograms or simply Fresnel/Fourier holograms. A Fourier hologram may be considered a Fourier domain/plane representation of the object or a frequency domain/plane representation of the object. A computer-generated hologram may also be calculated by coherent ray tracing or a point cloud technique, for example.

A computer-generated hologram may be encoded on a spatial light modulator arranged to modulate the amplitude and/or phase of incident light. Light modulation may be achieved using electrically-addressable liquid crystals, optically-addressable liquid crystals or micro-mirrors, for example.

A spatial light modulator typically comprises a plurality of individually-addressable pixels which may also be referred to as cells or elements. The light modulation scheme may be binary, multilevel or continuous. Alternatively, the device may be continuous (i.e. is not comprised of pixels) and light modulation may therefore be continuous across the device. The spatial light modulator may be reflective meaning that modulated light is output in reflection. The spatial light modulator may equally be transmissive meaning that modulated light is output in transmission.

A holographic projector may be provided using the system described herein. Such projectors have found application in head-up displays, “HUD”.

### SUMMARY

Aspects of the present disclosure are defined in the appended independent claims.

### Summary of Holographic Projection and Wavefront Replication

Broadly, the present disclosure relates to image projection. It relates to a method of image projection and an image projector which comprises a display device. The present disclosure also relates to a projection system comprising the image projector and a viewing system, in which the image projector projects or relays light from the display device to the viewing system. The present disclosure is equally applicable to a monocular and binocular viewing system. The viewing system may comprise a viewer's eye or eyes. The viewing system comprises an optical element having optical power (e.g., lens/es of the human eye) and a viewing plane (e.g., retina of the human eye/s). The projector may be referred to as a ‘light engine’. The display device and the image formed (or perceived) using the display device are spatially separated from one another. The image is formed, or perceived by a viewer, on a display plane. In some embodiments, the image is a virtual image and the display plane may be referred to as a virtual image plane. In other embodiments, the image is a real image formed by holographic reconstruction and the image is projected or relayed to the viewing plane. The image is formed by illuminating a diffractive pattern (e.g., hologram) displayed on the display device.

The display device comprises pixels. The pixels of the display device diffract light. In accordance with well-understood optics, the magnitude of the maximum diffraction angle is determined by the size of the pixels (and other factors such as the wavelength of light).

In embodiments, the display device is a spatial light modulator such as liquid crystal on silicon (“LCOS”) spatial light modulator (SLM). Light propagates over a range of diffraction angles (for example, from zero to the maximum diffractive angle) from the LCOS, towards a viewing entity/system such as a camera or an eye. In some embodiments, magnification techniques may be used to increase the range of available diffraction angles beyond the conventional maximum diffraction angle of an LCOS.

In some examples, an image (formed from the displayed hologram) is propagated to the eyes. For example, spatially modulated light of an intermediate holographic reconstruction/image formed either in free space or on a screen or other light receiving surface between the display device and the viewer, may be propagated to the viewer.

In some other examples, the (light of a) hologram itself is propagated to the eyes. For example, spatially modulated light of the hologram (that has not yet been fully transformed to a holographic reconstruction, i.e. image)—that may be informally said to be “encoded” with/by the hologram—is propagated directly to the viewer's eyes. A real or virtual image may be perceived by the viewer. In these embodiments, there is no intermediate holographic reconstruction/image formed between the display device and the viewer. It is sometimes said that, in these embodiments, the lens of the eye performs a hologram-to-image conversion or transform. The projection system, or light engine, may be configured so that the viewer effectively looks directly at the display device.

In accordance with the principles of well-understood optics, the range of angles of light propagating from a display device that can be viewed, by an eye or other viewing entity/system, varies with the distance between the display device and the viewing entity. At a 1 metre viewing distance, for example, only a small range of angles from an LCOS can propagate through an eye's pupil to form an image at the retina for a given eye position. The range of angles of light rays that are propagated from the display device, which can successfully propagate through an eye's pupil to form an image at the retina for a given eye position, determines the portion of the image that is ‘visible’ to the viewer. In other words, not all parts of the image are visible from any one point on the viewing plane (e.g., any one eye position within a viewing window such as eye-motion box.)

In some embodiments, the image perceived by a viewer is a virtual image that appears upstream of the display device—that is, the viewer perceives the image as being further away from them than the display device. Conceptually, it may therefore be considered that the viewer is looking at a virtual image through an ‘display device-sized window’, which may be very small, for example 1 cm in diameter, at a relatively large distance, e.g., 1 metre. And the user will be viewing the display device-sized window via the pupil(s) of their eye(s), which can also be very small. Accordingly, the field of view becomes small and the specific angular range that can be seen depends heavily on the eye position, at any given time.

A pupil expander addresses the problem of how to increase the range of angles of light rays that are propagated from the display device that can successfully propagate through an eye's pupil to form an image. The display device is generally (in relative terms) small and the projection distance is (in relative terms) large. In some embodiments, the projection distance is at least one—such as, at least two—orders of magnitude greater than the diameter, or width, of the entrance pupil and/or aperture of the display device (i.e., size of the array of pixels).

Use of a pupil expander increases the viewing area (i.e., user's eye-box) laterally, thus enabling some movement of the eye/s to occur, whilst still enabling the user to see the image. As the skilled person will appreciate, in an imaging system, the viewing area (user's eye-box) is the area in which a viewer's eyes can perceive the image. The present disclosure particularly relates to non-infinite virtual image distances—that is, near-field virtual images—but is equally applicable to virtual images formed at infinity or even real images formed downstream of the display device/hologram.

The display device may have an active or display area having a first dimension that may be less than 10 cms such as less than 5 cms or less than 2 cms. The propagation distance between the display device and viewing system may be greater than 1 m such as greater than 1.5 m or greater than 2 m. The optical propagation distance within the waveguide may be up to 2 m such as up to 1.5 m or up to 1 m. The method may be capable of receiving an image and determining a corresponding hologram of sufficient quality in less than 20 ms such as less than 15 ms or less than 10 ms.

Broadly, a system is disclosed herein that provides pupil expansion for an input light field or wavefront. The input light field may be a diffracted or holographic light field comprising diverging ray bundles and the display system may be described as hologram-to-eye. In this case, the input light field is spatially modulated in accordance with a hologram of an image. Alternatively, the input light field may be an image and the display system may comprise a screen, such as a diffuser, arranged to form the image thereon. In this case, the input light field is spatially modulated in accordance with an image. In both cases, the input light field is replicated to form a 1D or 2D array of replicas. For the avoidance of doubt, the present disclosure is equally applicable to both techniques. In particular, the coating or thin film or method of forming the same in accordance with the present disclosure is equally applicable to waveguiding and replicating a hologram or an image.

In the present disclosure, the term “replica” is merely used to reflect that spatially modulated light is divided such that a complex light field or wavefront is directed along a plurality of different optical paths. The word “replica” is used to refer to each occurrence or instance of the complex light field or wavefront after a replication event—such as a partial reflection-transmission by a pupil expander. Each replica travels along a different optical path. Some embodiments of the present disclosure relate to propagation of light that is encoded with a hologram, not an image—i.e., light that is spatially modulated with a hologram of an image, not the image itself. The person skilled in the art of holography will appreciate that the complex light field associated with propagation of light encoded with a hologram will change with propagation distance. Use herein of the term “replica” is independent of propagation distance and so the two branches or paths of light associated with a replication event are still referred to as “replicas” of each other even if the branches are a different length, such that the complex light field has evolved differently along each path. That is, two complex light fields are still considered “replicas” in accordance with this disclosure even if they are associated with different propagation distances—providing they have arisen from the same replication event or series of replication events.

As above, an optical waveguide for use as a pupil expander may lightguide or waveguide a light field or wavefront between a pair of parallel surfaces. This may be achieved by internal reflection between the parallel surfaces. A first surface of the pair of surfaces may be partially transmissive-reflective. A second surface of the pair of surfaces may be reflective. The light field will therefore be divided at each internal reflection at the first surface such that a plurality of replicas of the light field is transmitted through a region of the first surface that forms an output port of the waveguide. Thus, a viewing window (and eye-box) is enlarged by the waveguide.

The intensity and spectrum of each successive replica emitted by the waveguide is required to be substantially constant from replica to replica. For example, an integral of the intensity of the light of each replica may be substantially constant, a mean average of the intensity of the light of each replica may be substantially constant and/or a distribution of the intensity of the light of each replica may be substantially constant. Replicas having substantially constant intensity and spectra are referred to herein as being spatially homogenous and a waveguide emitting such replicas is referred to herein as providing spatially homogenous emission. Spatially homogenous replicas advantageously reduce or minimize the variability in the brightness of the image perceived (or different areas thereof) by a viewer moving around the (expanded) viewing window. Furthermore, the overall quality of the hologram received by the viewer (and/or the resulting image perceived by the viewer) may be improved, particularly if the hologram comprises a plurality of different wavelengths of light.

The intensity of the light being waveguided between the first and second surfaces of the waveguide will decrease after each division of the light field at the first surface. A sub-optimal waveguide may typically comprise a first surface with constant reflectivity. This results in the intensity of each successive replica decreasing. In other words, such conventional waveguides do not provide spatially homogenous emission.

A graded coating or gradient thickness coating can be applied to the waveguide to provide a first surface having a varying reflectivity and therefore transmissivity. In particular, the coating may be arranged so that the transmissivity of the first surface increases in the direction of waveguiding. The graded coating may be arranged such that the increased transmissivity of the first surface in the direction of waveguiding accounts (e.g. at least partially compensates) for the decrease in the intensity of light being light guided. However, current graded coatings often result in high absorption losses of the waveguided light. Furthermore, these coatings typically allow for very limited control of spectral performance, particularly disadvantageous when the light to be waveguided comprises multiple wavelengths. While some improved graded coatings are available, these are expensive, time consuming and complex to manufacture and generally cannot be manufactured reliably. For example, such coatings may comprise a plurality (often 20 or more) layers of dielectric material, each layer having a unique percentage change of the thickness from a first end of the layer to a second end. Such a complex layered structure may be necessary to provide substantially spatially homogenous emission for the full visible spectrum but is slow to manufacture and difficult to manufacture reliably (for example, a moving grader may be required to be present in the coating chamber).

### Summary of Waveguide Coating

Broadly, the present disclosure addresses a technical problem of providing a spatially homogenous emission from a waveguide pupil expander such that the intensity and spectrum of each replica is substantially similar. The present disclosure proposes an improved waveguide pupil expander which provides substantially homogeneous emission at least at specific wavelengths such as a red, green and blue wavelength. A first surface of the waveguide comprises a plurality of alternating layers of a first and a second dielectric that differ in refractive index. In some examples, each layer has a unique percentage change of thickness. In some examples, each layer of dielectric has a percentage change of thickness.

The multilayer structure resulting from conventional design techniques is very complex and has low suitability for industrial scale-up. The complexity is partly caused by the need to achieve uniformity at three different wavelengths. This design process has been rethought and focused on restricting it in ways that simplify the manufacturing method that will be needed and relaxing it in other ways that do not impact the image-forming (e.g. holographic) process. In particular, focus has been placed on how to increase speed and reduce the number of hardware changes required during coating because these may require time inefficient processes related to opening the coating chamber such as re-evacuating the chamber.

According to examples, a waveguide is provided. The waveguide comprises a pair of parallel/complementary surfaces arranged to provide waveguiding therebetween. A first surface of the pair of parallel surfaces comprises a plurality of layers of a first dielectric and a plurality of layers of second dielectric arranged in an alternating configuration. Each layer of the first and second dielectric has a first end and a second end. The first end may be a (light) input end and the second end may be a (light) output end for the final replica or the end of an output port/window. A percentage change in the thickness of each layer from the first end to the second end of that layer has one of a plurality of discrete (e.g. allowable) values. The total number of layers of the first and second dielectric is greater than the total number of discrete values. A difference in refractive index between the first dielectric and second dielectric is greater than 0.4, optionally greater than 0.5 (e.g., at 633 nm).

References to “percentage change in the thickness” of a layer herein refer to the percentage change in thickness of that layer from the first end of that layer to the second end of that layer, unless specified otherwise. The percentage change in the thickness of a layer may be: 100×(t_{f}−tᵢ)/tᵢ, wherein tᵢ is the thickness of the respective layer at the first end and t_{f} is the thickness of the respective layer at the second end.

Generally, each layer of the plurality of layers may be parallel to the other layers. The first end of each of layer may be aligned with the first end of the other layers and the second end of each layer may be aligned with the other layers. In other words, each layer may have a substantially similar length and/or width as the other layers but may differ in thickness or depth. The plurality of layers of the first and second dielectric may be referred to as a stack of layers or, simply, dielectric stack.

As used herein, the “alternating configuration” of the layers of the first and second dielectric means that each layer of the first dielectric is separated from the next closest layer(s) of first dielectric by a layer of the second dielectric, and vice versa.

In some examples, more than two, optionally four or more, optionally 6 or more, optionally 8 or more, optionally 10 or more layers of the plurality of layer may have the same percentage change of thickness from the respective first end to the respective second end (and so these layers may be associated with the same discrete value). In some examples, the layers that have the same percentage change of thickness as each other are layers of the same dielectric (i.e. all layers having a particular percentage change of thickness value are layers of the first dielectric or layers of the second dielectric).

Each of the layers of the first or second dielectric may increase or decrease in thickness in the direction of waveguiding. A first direction may be defined from the first end to the second end of each of the plurality of layers. The pair of parallel surfaces may be arranged to provide waveguiding in the first direction. In other words, light waveguided by the pair of surfaces may interact with the first end before interacting with the second end. Furthermore, each of the layers of the first or second dielectric may increase or decrease in thickness in the first direction.

The minimum thickness of each of the plurality of layers of the first and second dielectric, as well as the discrete values for the percentage change in thickness, may be selected to provide a waveguide with desired optical properties, in particular with a desired transmissive behaviour such that a spatially homogenous emission is generated. The parameters may depend on (among other things) the material properties (in particular, the refractive index) of the first and second dielectric, the angle of incidence of light entering the waveguide, the wavelength(s) of the incident light and the distance between the pair of parallel surfaces of the waveguide. As will be appreciated by the skilled person, there will be a plurality (usually a relatively large number) of arrangements of the plurality of layers that provide a waveguide with desired optical properties. However, common to all of these arrangements are the advantages that the layered structure of the first surface provides desired optical properties and can be manufactured quickly, inexpensively and reliably.

One example of a fast, inexpensive and reliable method of manufacturing the layers of the first and second dielectric may comprise forming the layers by depositing the respective dielectric material on a waveguide substrate. A shadow mask may be used to control the flow of the dielectric material onto the substrate. Preferably, a shadow mask with a trapezoidal shape may be used. The percentage change in thickness of each layer may be determined by the shape of the mask and the overall thickness of each layer may be determined by the length of time that the dielectric material is allowed to flow. When the mask is trapezoidal, the percentage change in thickness of each layer may correspond to a percentage change in the short base to the long base of the trapezoid shape of the shadow mask. A different mask may be associated with each of the discrete values. For example, if there are first to fourth percentage change values then four different masks may be used to manufacture the layers of the coating. The waveguide substrate may advantageously simply be moved between different material sources having different masks.

Preferably, the rate of change of the thickness of each layer may be constant. In other words, each of the layers may have a linear profile. It may be simpler to manufacture dielectric layers having a linear profile. Furthermore, the skilled person will appreciate that it may be more straightforward to calculate/determine discrete allowable values for a stack of layers having a linear profile.

In some embodiments, the first surface may provide a plurality, n, of light emission zones for light waveguided between the first surface and second surface. The plurality of light emission zones may be distributed along a length of the first surface, in the direction of waveguiding. A replica of the input wavefront may be generated at each emission zone. The first end of each layer of the first and second dielectric layer may be at or adjacent to the first light emission zone. The second end of each layer of the first and second dielectric later may be at or adjacent to the nth light emission zone.

An angle of internal incidence at each emission zones may be in the range 0 to 70 degrees, preferably in the range of 10 to 50 degrees.

At other wavelengths (i.e. not the first, second and third visible wavelength), the transmissivity of the first surface may or may not increase in the direction of waveguiding. As previously described, the waveguide of the present disclosure may be particularly advantageous in the context of waveguiding light at discrete wavelengths, rather than waveguiding light having a continuous spectrum. The inventors have appreciated that the parameters such as thickness and the values for the percentage change of thickness of the plurality of layers of the first and second dielectrics may be selected to provide a desired changing transmissivity behaviour at the first, second and third wavelengths only and that there may be no need for the layers to provide that same transmissivity behaviour at other wavelengths. The inventors have found that by confining the problem of providing a changing transmissivity behaviour to only certain wavelengths, a coating comprising multiple layers having the same rate of change of thickness can provide the desired transmissivity behaviour which, as above, can be manufactured inexpensively, quickly and reliably while still providing acceptable transmissive properties.

The first wavelength, referred to above, may preferably be in the range 630-670 nm. The second wavelength may preferably be in the range 500-540 nm. The third wavelength may preferably be in the range 430-470 nm. In other words, the first wavelength may correspond to red visible light. The second wavelength may correspond to green visible light. The third wavelength may correspond to blue visible light.

Preferably, the transmissivity of the first surface at each emission point, T(n), may satisfy the following equation: T(n)=(T(n−1))/([1−T(n−1)]×[1−L]) wherein L is an optical loss factor of the waveguide material.

The first dielectric may be a first oxide, fluoride, sulfide or nitrate of a first transition metal or semiconductor. The second dielectric may be a second oxide, fluoride, sulfide or nitrate of a second transition metal or semiconductor. In some embodiments, the first dielectric comprises silicon, titanium, tantalum or hafnium. In some embodiments, the second dielectric comprises another of silicon, titanium, tantalum or hafnium.

Each layer may have a thickness in the range 2 to 300 nm. The thickness of each layer may not fall outside of this range at any point between the first end and second end. In some embodiments, each layer may have a thickness in the range 20 to 300 nm.

A minimum thickness of each layer may be between 2 and 300 nm, optionally between 20 and 300 nm. A maximum thickness of each layer may be between 2 and 300 nm, optionally between 20 and 300 nm. The minimum thickness of each layer is less than the maximum thickness of that respective layer. The minimum or maximum thickness of each layer may be at the first end of that layer. The other of the minimum or maximum thickness of the respective layer may be at the second end of that layer.

At least one percentage change in thickness may be positive. At least one percentage change in thickness may be negative.

Each percentage change in thickness may be in the range −150% to +150%.

The number of layers of the plurality of layers may be at least 10, optionally at least 15, optionally at least 20. The number of layers of the plurality of layers may be in the range 10 to 30, optionally, 15-25.

### Summary of an Improved Waveguide Coating

In overview, some examples of the present disclosure relate to forming a transmission coating comprising one or more layers. There is disclosed herein a device and method for providing a coating having a thickness gradient defined by the shape of a shadow mask.

The present disclosure is synergistic with the method of U.S. Pat. No. 11,852,832 and British patent application GB 2402387.1 which are each incorporated herein by reference in their entirety. U.S. Pat. No. 11,852,832 discloses an improved efficiency method of fabricating graded coatings on a waveguide. The patent discloses that a percentage change in the thickness of each layer of the coating, from the first end to the second end, has one of a plurality of discrete allowed values, wherein the total number of layers is greater than the total number of discrete allowable values. British patent application GB 2402387.1 discloses a method of optimising coating by measuring a deviated coating function and modifying the coating design based on the deviated coating function in order that an improved coating may be provided without making hardware changes within the coating chamber such as changing the coating target.

Waveguides with graded transmissions coatings are an important component in a holographic projector system such as a head-up display in order to achieve two dimensional pupil expansion and increase the eye-box size and field of view. Gradient shadow masks may be used to tailor spatially varying coating thicknesses, which result in graded transmission, e.g. in a bespoke coating design. Implementing this type of gradient coatings requires fundamental changes and optimisations to the operation of existing coating machines which are typically designed for applying uniform/continuous coating applications.

Drum coaters are commonly used in coating applications due to a high deposition rate and large coating area per batch. In an example of a magnetron sputtering drum coater, the effective coating area of the entire drum can be described as a rectangle with two axes: a rotational direction and an axial or controlled direction. In an ideal circular drum, the coating would have an ideal uniformity in the rotational direction provided that the drum rotation is maintained at a constant speed. In reality, the geometry of the drum is not perfectly circular, such that minor non-uniform coating thickness is introduced. This can be compensated by high frequency power modulation associated with the rotational speed. In the axial or controlled direction, coating uniformity is controlled by the magnetron sputtering process, including the distribution of target material, magnetic field, gas, shadow mask, etc. Existing coating machines are designed to obtain maximum uniformity by fine tuning these parameters, e.g. by using a target with a desired physical variation along the axial/controlled direction, magnetic field distribution, gas distribution, providing a shadow mask with an arc shape. Control of these parameters compensates for non-uniformity in the coating thickness along the entirety of the axial/controlled direction.

Therefore, there is an existing prejudice in the field of design and manufacture of coating machines that the applied thickness of coatings onto sample substrates should be as uniform as possible.

Furthermore, drum coating machines are typically designed to house a relatively large quantity of substrates that may be tiled in both the rotational direction and the axial/controlled direction. This tiled arrangement does not require any additional adjustments or considerations in conventional uniform coating applications, since the conventional drum coating machine is designed to apply uniform coating thicknesses in both directions.

The inventors have discovered and developed a coating device and method that modifies existing coating machine architecture to allow for graded coatings to be applied to samples with a desired gradient by incorporating a periodic shadow mask.

A number of technical obstacles were overcome by the inventors in order to implement an effective gradient shadow mask that may be used to manufacture suitable coatings for pupil expanders.

Due to the changing shape of a periodic shadow mask, inventors identified that the mask can affect the gas distribution in the axial/controlled direction. In particular, the inventors identified that the presence of sharp corners on the shadow mask creates local gas turbulence that affects the coating deposition rate relatively far from the corner in the axial/controlled direction, thus creating uncontrolled variations in coating thickness. This formed a technical barrier to implementing gradient shadow masks which the inventors have overcome as set out below.

Another related technical obstacle is that the region of shadow mask corresponding to a group of substrates may interfere with the coating of an adjacent group of substrates. The inventors have therefore identified that a certain clearance is needed between tiled groups of substrates in order to avoid this interference effect.

Additionally, in order to reduce the gradient slope of any particular part of the shadow mask, the inventors identified that a pair of shadow masks (e.g. two angled sides of a trapezoidal aperture) may be used instead of a single mask such that the desired gradient is shared, thus resulting in the individual slopes of the shadow mask being less steep.

### SUMMARY OF ASPECTS AND EMBODIMENTS OF THE PRESENT DISCLOSURE

A first aspect of the present disclosure relates to a coating device. The coating device comprises a sample carrier. For example, the sample carrier may comprise a planar surface suitable for mounting a plurality of samples. By way of example only, the sample carrier may be in the form of an elongate rectangular sheet (e.g. formed of metal). The coating device comprises a plurality of sample positions located on the sample carrier. In other words, there are a plurality of pre-defined positions on the sample carrier at which individual samples may be positioned. For example, the sample positions may be provided on the sample carrier as markings or indentations having the shape of the samples. Alternatively, the sample positions may not be physically on the sample carrier but may instead be stored in a computer memory or the like. The plurality of sample positions is arranged in a plurality of groups distributed along a first dimension of the sample carrier. In other words, each group may be located at various different positions along the first dimension (e.g. an elongate dimension) of the sample carrier. In some examples, each group of sample positions has an identical layout to each of the other groups, but in some alternative examples some or all of the groups may have a different layout of sample positions. Each group of sample positions comprises a first row of sample positions and a second row of sample positions each extending along a second dimension of the sample carrier. The first dimension is perpendicular to the second dimension. For example, the first dimension may be parallel to an elongate direction of the sample carrier, and the second dimension may be parallel to a shorter dimension of the sample carrier (e.g. for a rectangular sample carrier). In other words, each group comprises a pair of rows. Each row comprises one or more sample positions. In other words, each group comprises at least two sample positions (i.e. when each row consists of a single sample position, one sample position making up each row). The two rows of each group may each extend in the second dimension and may be spaced relative to one another along the first dimension. In some examples, the sample positions may be arranged on a grid/array (with uneven spacing). A spacing between the first row and the second row within each group is smaller than a spacing between groups. In other words, the first and second rows may be separated/spaced apart in the first dimension by a first distance and the groups (each comprising respective first and second rows) may be separated/spaced apart in the first dimension by a second distance, wherein the second distance is greater than the first distance. The coating device comprises a shadow mask. For example, the shadow mask may be arranged to partially block/control a flow of a coating material being emitted from a source. The shadow mask comprises a plurality of aperture components arranged along the first dimension. In some examples, the aperture components may be individual apertures in the shadow mask. In other examples, some or all of the aperture components may form a continuous aperture or series of continuous apertures (i.e. the aperture components may combine into a continuous aperture(s)). Each aperture component is aligned with a corresponding row of sample positions. In other words, the aperture components may be aligned in a one-to-one correspondence with specific rows of sample positions. The plurality of aperture components is formed by alternating first components and second components. In other words, each group of sample positions may have a corresponding first aperture component and second aperture component. Each first aperture component comprises an increase in aperture size in the second dimension and each second aperture component comprises a decrease in aperture size in the second dimension. In other words, the aperture becomes wider along the first dimension in a given direction for the first components and the aperture becomes narrower in the first dimension in the given direction for the second components. The rate of change of aperture size for each component can be understood as a shadow mask gradient which in turn results in a gradient in the amount of coating material that is deposited onto a sample located at one of the sample positions. Each first component is aligned with a respective first row of the plurality of groups, and each second component is aligned with a respective second row of the plurality of groups.

As discussed above, a technical hurdle overcome by the inventors is that neighbouring parts of a graded shadow mask may interfere with the coating uniformity of an adjacent group of samples/substrates. The inventors therefore identified this problem and implemented the claimed solution of ensuring that the spacings between groups of sample positions is greater than the spacing between a pair of sample position rows within a group. This reduces the effect of interference from a neighbouring part of the shadow mask, resulting in greater control over the thickness gradient of the coating.

Furthermore, this arrangement is advantageous since it avoids the need for abrupt changes in shadow mask gradient. As discussed herein, abrupt changes and “sharp” corners in the shadow mask may induce turbulence in a coating gas as it travels past the shadow mask to deposit onto the samples.

Therefore, a coating device is provided that makes full use of the coating capacity of the coating device without compromising on reliability or optical performance.

The first rows of sample positions may have a first orientation with respect to the first dimension, and the second rows of sample positions may have a second orientation with respect to the first dimension.

The first orientation may be opposite to the second orientation. In other words, the samples or sample positions may be asymmetrical (either in terms of their geometry or another physical (e.g. optical) property) about an axis parallel to the second dimension. In this way, such asymmetrical samples in two different rows may have the same gradient of coating applied to them since the aperture gradient of the first component of the shadow mask (aligned with a first row having a first orientation) may be opposite to that of the second component of the shadow mask (aligned with a second row having a second orientation opposite the first orientation). This arrangement may be described as a “tiled back-to-back” arrangement.

The coating device may further comprise a gradient transition between each of the alternating first components and second components of the shadow mask. In other words, a gradient transition may be understood as a region of the shadow mask where the direction of the gradient/slope changes. Each gradient transition may comprise a rounded corner aligned with a corresponding spacing between rows of sample positions. In other words, an abrupt change in mask gradient is avoided by rounding the corners of the mask when the direction of the mask gradient changes. Rounding the corners of the shadow mask is advantageous since it reduces the amount of gas turbulence induced during coating, resulting in a more controlled gradient coating.

A radius of curvature of the rounded corners may be smaller for gradient transitions aligned with spacings between the first rows and second rows within a group compared to gradient transitions aligned with spacings between groups. In other words, the gradient transition within a group of rows may occur more rapidly in the first dimension compared to a gradient transition between groups of rows. The larger/smaller gradient transitions may therefore aligned with a respective larger/smaller spacing between rows of samples. Therefore, the rate of change (abruptness of change) of gradient is minimised within the constraint of the respective spacings, thus reducing the detrimental gas turbulence while also maximising the capacity of the sample carrier to coat as many samples as possible.

The radius of curvature for each rounded corner may be smaller than the respective spacing between the first rows and second rows within a group or the respective spacing between groups. In other words, the rounded corners may be understood as expanding the gradient transition and are rounded such that the gradient transition is complete for the parts of the shadow mask aligned with the sample positions. That is, the gradient transitions are only aligned/overlapping with the spacings, not the sample positions. Therefore, the corners of the shadow mask are rounded to mitigate the problem of gas turbulence, and the radius of curvature of the rounded corner may be chosen to minimize the abruptness of the gradient transition while also ensuring that the gradient transition does not adversely affect the desired gradient transition of the shadow mask for the respective sample position(s).

A subset of the gradient transitions may comprise a bridging link between opposite sides of the shadow mask in the second dimension. The subset may comprise gradient transitions where the aperture size is smaller in the second dimension. In other words, the bridging link connects opposite sides of the shadow mask where the aperture is narrowed. This advantageously results in a further reduction of the corner “sharpness” by modifying the angle of the edge of the shadow mask.

The plurality of aperture components may be substantially trapezoidal, and the parallel sides of the trapeziums may extend in the second dimension. In other words, the angled sides of the trapeziums provide the gradient of the shadow mask. The parallel sides of the trapeziums may be physically represented as edges of the shadow mask or may substantially overlap with the parallel sides of an adjacent trapezium such that the parallel sides are “virtual” sides of a trapezium traced between the respective ends of the angled sides of the trapezium. Advantageously, both of the two angled sides of the trapezium contribute to the coating gradient by both sides reducing/blocking the flow of coating material, as opposed to using a single edge to apply the coating gradient.

The plurality of trapezoidal aperture components may abut one another in pairs to form a plurality of hexagonal aperture components. In other words, and as explained above with respect to the trapezoidal aperture components, the parallel sides of the trapeziums may substantially overlap with an adjacent trapezoidal aperture component, such that the combination of the two trapezoidal aperture components forms a hexagonal aperture. In the aforementioned example including the use of bridging links, the inclusion of the bridging links forms a plurality of discrete hexagonal apertures.

The increase in aperture size of the first components may be equal and opposite to the decrease in aperture size of the second components. In other words, the first and second aperture components may be mirror images of one another, flipped along the second dimension. In this way, the same profile of coating gradient may be applied to tiled back-to-back rows of samples, allowing for a space efficient coating layout while also minimizing gas turbulence issues.

The coating device may further comprise a source arranged to coat a plurality of samples with a coating material, and wherein the shadow mask may be positioned between the source and the sample carrier. In examples, the source may be a target may be a desired coating material that is bombarded with a gas (e.g. argon) causing the target to eject coating material towards the sample carrier.

The coating device may further comprise a coating driver arranged to control the source, wherein the coating driver may comprise at least one selected from the group comprising: a magnetic bar controller arranged to change the magnitude of a magnetic field at a plurality of positions of the source; a pressure controller arranged to change the pressure of a gas of the coating device; and a magnet rotator arranged to control a direction of deposition.

The coating device may further comprise a plurality of samples located at some or all of the sample positions. In other words, all of the sample positions on a sample carrier do not necessarily need to be populated.

The plurality of samples may comprise waveguides. As discussed above, applying a graded coating to a waveguide is an important component for a holographic projector in order to achieve two-dimensional pupil expansion.

An angle of the rounded corners may be greater than 90 degrees and smaller than 120 degrees. The inventors have identified that corners of the shadow mask having angles outside of this range may result in unacceptable levels of gas turbulence resulting in an uncontrolled gradient of coating thickness.

The plurality of sample positions may comprise at least six rows of one or more sample positions. In other words, the claimed layout of sample positions allows for series production of a large number of coated samples at once, allowing for high efficiency and high production rate.

The coating device may further comprise a drum configured to house at least the sample carrier; and a source positioned at the centre of the drum. The shadow mask may be positioned between the source and the sample carrier. The drum may be configured to rotate at a controllable speed (e.g. a first speed of a plurality of discrete speeds or from a continuous range of speeds) in order to coat a plurality of samples located at the plurality of sample locations with a coating material. In examples, the coating device comprises a plurality of sample carriers, each as described above, arranged in a substantially circular layout around the perimeter of the drum. In examples, the coating device may further comprise a vacuum chamber arranged to be filled with gas that facilitates coating such as physical vapour deposition e.g. sputtering. The vacuum chamber may house the sample carrier, source and shadow mask. The vacuum chamber may house other components that are externally controllable by the coating driver—e.g. without opening the vacuum chamber.

A second aspect of the disclosure relates to a method for coating a plurality of samples. The method comprises arranging a plurality of samples on a sample carrier at a plurality of sample positions. The plurality of sample positions are arranged in a plurality of groups distributed along a first dimension of the sample carrier. Each group of sample positions are arranged to comprises a first row of sample positions and a second row of sample positions each extending along a second dimension of the sample carrier. The first dimension is perpendicular to the second dimension. Each row comprises one or more sample positions. A spacing between the first row and second row within each group is smaller than a spacing between groups. The method further comprises providing a shadow mask. The shadow mask comprises a plurality of aperture components arranged along the first dimension. Each aperture component is aligned with a corresponding row of sample positions. The plurality of aperture components are formed by alternating first components and second components. Each first component comprises an increase in aperture size in the second dimension. Each second component comprises a decrease in aperture size in the second dimension. Each first component is aligned with a respective first row of the plurality of groups, and each second component is aligned with a second row of the plurality of groups.

### SUMMARY OF TERMS

The term “hologram” is used to refer to the recording which contains amplitude information or phase information, or some combination thereof, regarding the object. The term “holographic reconstruction” is used to refer to the optical reconstruction of the object which is formed by illuminating the hologram. The system disclosed herein is described as a “holographic projector” because the holographic reconstruction is a real image and spatially-separated from the hologram. The term “replay field” is used to refer to the 2D area within which the holographic reconstruction is formed and fully focused. If the hologram is displayed on a spatial light modulator comprising pixels, the replay field will be repeated in the form of a plurality diffracted orders wherein each diffracted order is a replica of the zeroth-order replay field. The zeroth-order replay field generally corresponds to the preferred or primary replay field because it is the brightest replay field. Unless explicitly stated otherwise, the term “replay field” should be taken as referring to the zeroth-order replay field. The term “replay plane” is used to refer to the plane in space containing all the replay fields. The terms “image”, “replay image” and “image region” refer to areas of the replay field illuminated by light of the holographic reconstruction. In some embodiments, the “image” may comprise discrete spots which may be referred to as “image spots” or, for convenience only, “image pixels”.

The terms “encoding”, “writing” or “addressing” are used to describe the process of providing the plurality of pixels of the SLM with a respective plurality of control values which respectively determine the modulation level of each pixel. It may be said that the pixels of the SLM are configured to “display” a light modulation distribution in response to receiving the plurality of control values. Thus, the SLM may be said to “display” a hologram and the hologram may be considered an array of light modulation values or levels.

It has been found that a holographic reconstruction of acceptable quality can be formed from a “hologram” containing only phase information related to the Fourier transform of the original object. Such a holographic recording may be referred to as a phase-only hologram. Embodiments relate to a phase-only hologram but the present disclosure is equally applicable to amplitude-only holography.

The present disclosure is also equally applicable to forming a holographic reconstruction using amplitude and phase information related to the Fourier transform of the original object. In some embodiments, this is achieved by complex modulation using a so-called fully complex hologram which contains both amplitude and phase information related to the original object. Such a hologram may be referred to as a fully-complex hologram because the value (grey level) assigned to each pixel of the hologram has an amplitude and phase component. The value (grey level) assigned to each pixel may be represented as a complex number having both amplitude and phase components. In some embodiments, a fully-complex computer-generated hologram is calculated.

Reference may be made to the phase value, phase component, phase information or, simply, phase of pixels of the computer-generated hologram or the spatial light modulator as shorthand for “phase-delay”. That is, any phase value described is, in fact, a number (e.g. in the range 0 to 2π) which represents the amount of phase retardation provided by that pixel. For example, a pixel of the spatial light modulator described as having a phase value of π/2 will retard the phase of received light by π/2 radians. In some embodiments, each pixel of the spatial light modulator is operable in one of a plurality of possible modulation values (e.g. phase delay values). The term “grey level” may be used to refer to the plurality of available modulation levels. For example, the term “grey level” may be used for convenience to refer to the plurality of available phase levels in a phase-only modulator even though different phase levels do not provide different shades of grey. The term “grey level” may also be used for convenience to refer to the plurality of available complex modulation levels in a complex modulator.

The hologram therefore comprises an array of grey levels—that is, an array of light modulation values such as an array of phase-delay values or complex modulation values. The hologram is also considered a diffractive pattern because it is a pattern that causes diffraction when displayed on a spatial light modulator and illuminated with light having a wavelength comparable to, generally less than, the pixel pitch of the spatial light modulator. Reference is made herein to combining the hologram with other diffractive patterns such as diffractive patterns functioning as a lens or grating. For example, a diffractive pattern functioning as a grating may be combined with a hologram to translate the replay field on the replay plane or a diffractive pattern functioning as a lens may be combined with a hologram to focus the holographic reconstruction on a replay plane in the near field.

Particular embodiments of the disclosure are set out in the following numbered list of items, which may be combined in any number and in any combination not technically or logically inconsistent:

Item 1. A method of coating a plurality of waveguides for head-up display, the method comprising:
forming a first group of waveguides by:
   arranging a first row of one or more first waveguides in a first orientation, the first row of one or more first waveguides being an odd-numbered row of waveguides; and
   arranging a second row of one or more second waveguides in a second orientation, wherein the second orientation is opposite the first orientation, such that the first row of one or more first waveguides opposes the second row of one or more second waveguides, and such that the first row of one or more first waveguides is spaced apart from the second group of one or more second waveguides by a first row spacing, the second row of one or more second waveguides being an even-numbered row of waveguides;
forming a second group of waveguides by:
   arranging a third row of one or more third waveguides in the first orientation, the third row of one or more third waveguides being an odd-numbered row of waveguides; and
   arranging a fourth row of one or more fourth waveguides in the second orientation such that the third row of one or more third waveguides opposes the fourth row of one or more fourth waveguides, and such that the third row of one or more third waveguides is spaced apart from the fourth row of one or more fourth waveguides by a second row spacing, the fourth row of one or more fourth waveguides being an even-numbered row of waveguides;
spacing the first group of waveguides and second group of waveguides such that a gap between the first group of waveguides and second group of waveguides is greater than the first row spacing, and the gap between the first group of waveguides and second group of waveguides is greater than the second row spacing; and
coating the first group of waveguides and second group of waveguides through a shadow mask comprising a stacked array of hexagonal apertures comprising a series of alternating first sections having decreasing aperture width and second sections having increasing aperture width, wherein the first sections are aligned with odd-numbered rows of waveguides and the second sections are aligned with even-numbered rows of waveguides.

Item 2. The method of Item 1, wherein the stacked array of hexagonal apertures is arranged such that adjacent hexagonal aperture components directly abut one another.

Item 3. The method of Item 1, wherein the stacked array of hexagonal apertures is arranged such that adjacent hexagonal aperture components are separated by a bridging link of the shadow mask.

Item 4. The method of any preceding Item, wherein the shadow mask comprises a gradient transition between each of the alternating first sections and second sections, wherein each gradient transition comprises a rounded corner aligned with one of:
(i) the spacing between the first row of one or more first waveguides and the second row of one or more second waveguides;
(ii) the spacing between the third row of one or more third waveguides and the fourth row of one or more fourth waveguides; or
(iii) the gap between the first group of waveguides and the second group of waveguides.

Item 5. The method of Item 4, wherein a radius of curvature of the rounded corners is smaller for rounded corners aligned with (i) the spacing between the first row of one or more first waveguides and the second row of one or more second waveguides and (ii) the spacing between the third row of one or more third waveguides and the fourth row of one or more fourth waveguides, compared to a radius of curvature for rounded corners aligned with (iii) the gap between the first group of waveguides and the second group of waveguides.

Item 6. The method of Item 5, wherein a radius of curvature of the rounded corner is smaller than the respective (i) spacing between the first row of one or more first waveguides and the second row of one or more second waveguides; (ii) spacing between the third row of one or more third waveguides and the fourth row of one or more fourth waveguides; or (iii) gap between the first group of waveguides and the second group of waveguides.

Item 7. The method of Item 6 wherein an angle of the rounded corners is greater than 90 degrees and smaller than 120 degrees.

Item 8. The method of any preceding Item, wherein each of the alternating first sections of the shadow mask and second sections of the shadow mask are substantially trapezoidal components which abut one another to form the stacked array of hexagonal apertures.

Item 9. The method of any preceding Item, wherein the step of coating the first group of waveguides and second group of waveguides through the shadow mask comprises:
arranging a source to output a coating material; and
positioning the shadow mask between the source and the first group of waveguides and second group of waveguides.

Item 10. The method of Item 9, wherein the step of coating the first group of waveguides and second group of waveguides through the shadow mask further comprises providing a coating driver arranged to control the source, wherein the coating driver comprises at least one selected from the group comprising: a magnetic bar controller arranged to change the magnitude of a magnetic field at a plurality of positions of the source, a pressure controller arranged to change the pressure of a gas; and a magnet rotator arranged to control a direction of deposition of the coating material.

Item 11. The method of Item 10, further comprising arranging the first group of waveguides and second group of waveguides on a sample carrier, and wherein the step of coating the first group of waveguides and second group of waveguides through the shadow mask further comprises:
configuring a drum to house the sample carrier; and
positioning the source at the centre of the drum, wherein the shadow mask is positioned between the source and the sample carrier, and
rotating the drum at a determined speed in order to coat the first group of waveguides and second group of waveguides with the coating material.

Item 12. A coating device comprising:
a sample carrier;
a plurality of waveguides arranged on the sample carrier in a first group of waveguides and a second group of waveguides,
wherein the first group of waveguides comprises:
   a first row of one or more first waveguides arranged in a first orientation, the first row of one or more first waveguides being an odd-numbered row of waveguides; and
   a second row of one or more second waveguides arranged in a second orientation, wherein the second orientation is opposite the first orientation, such that the first row of one or more first waveguides opposes the second row of one or more second waveguides, and such that the first row of one or more first waveguides is spaced apart from the second group of one or more second waveguides by a first row spacing, the second row of one or more second waveguides being an even-numbered row of waveguides;
wherein the second group of waveguides comprises:
   a third row of one or more third waveguides arranged in the first orientation, the third row of one or more third waveguides being an odd-numbered row of waveguides; and
   a fourth row of one or more fourth waveguides arranged in the second orientation such that the third row of one or more third waveguides opposes the fourth row of one or more fourth waveguides, and such that the third row of one or more third waveguides is spaced apart from the fourth row of one or more fourth waveguides by a second row spacing, the fourth row of one or more fourth waveguides being an even-numbered row of waveguides;
wherein the first group of waveguides and second group of waveguides are spaced such that a gap between the first group of waveguides and second group of waveguides is greater than the first row spacing, and the gap between the first group of waveguides and second group of waveguides is greater than the second row spacing;
a source arranged to coat the plurality of waveguides with a coating material; and
a shadow mask positioned between the source and the sample carrier, the shadow mask comprising a stacked array of hexagonal apertures comprising a series of alternating first sections having decreasing aperture width and second sections having increasing aperture width, wherein the first sections are aligned with odd-numbered rows of waveguides and the second sections are aligned with even-numbered rows of waveguide.

Item 13. The coating device of Item 12, wherein the stacked array of hexagonal apertures is arranged such that adjacent hexagonal aperture components directly abut one another.

Item 14. The coating device of Item 12, wherein the stacked array of hexagonal apertures is arranged such that adjacent hexagonal aperture components are separated by a bridging link of the shadow mask.

Item 15. The coating device of any of Items 12 to 14, wherein the shadow mask comprises a gradient transition between each of the alternating first sections and second sections, wherein each gradient transition comprises a rounded corner aligned with one of:
(i) the spacing between the first row of one or more first waveguides and the second row of one or more second waveguides;
(ii) the spacing between the third row of one or more third waveguides and the fourth row of one or more fourth waveguides; or
(iii) the gap between the first group of waveguides and the second group of waveguides.

Item 16. The coating device of Item 15, wherein a radius of curvature of the rounded corners is smaller for rounded corners aligned with (i) the spacing between the first row of one or more first waveguides and the second row of one or more second waveguides and (ii) the spacing between the third row of one or more third waveguides and the fourth row of one or more fourth waveguides, compared to a radius of curvature for rounded corners aligned with (iii) the gap between the first group of waveguides and the second group of waveguides.

Item 17. The coating device of Item 16, wherein a radius of curvature of the rounded corner is smaller than the respective (i) spacing between the first row of one or more first waveguides and the second row of one or more second waveguides; (ii) spacing between the third row of one or more third waveguides and the fourth row of one or more fourth waveguides; or (iii) gap between the first group of waveguides and the second group of waveguides.

Item 18. The coating device of Item 17 wherein an angle of the rounded corners is greater than 90 degrees and smaller than 120 degrees.

Item 19. The coating device of any of Items 12 to 18, wherein each of the alternating first sections of the shadow mask and second sections of the shadow mask are substantially trapezoidal components which abut one another to form the stacked array of hexagonal apertures.

Item 20. The coating device of any of Items 12 to 19, further comprising:
a drum configured to house at least the sample carrier; and
wherein the shadow mask is positioned between the source and the sample carrier,
wherein the drum is configured to rotate at a determined speed in order to coat the plurality of with the coating material.

Item 21. A coating device comprising:
a sample carrier;
a plurality of sample positions arranged on the sample carrier in a first group of sample positions and a second group of sample positions,
wherein the first group of sample positions comprises:
   a first row of one or more first sample positions arranged in a first orientation, the first row of one or more first sample positions being an odd-numbered row of sample positions; and
   a second row of one or more second sample positions arranged in a second orientation, wherein the second orientation is opposite the first orientation, such that the first row of one or more first sample positions opposes the second row of one or more second sample positions, and such that the first row of one or more first sample positions is spaced apart from the second group of one or more second sample positions by a first row spacing, the second row of one or more second sample positions being an even-numbered row of sample positions;
wherein the second group of sample positions comprises:
   a third row of one or more third sample positions arranged in the first orientation, the third row of one or more third sample positions being an odd-numbered row of sample positions; and
   a fourth row of one or more fourth sample positions arranged in the second orientation such that the third row of one or more third sample positions opposes the fourth row of one or more fourth sample positions, and such that the third row of one or more third sample positions is spaced apart from the fourth row of one or more fourth sample positions by a second row spacing, the fourth row of one or more fourth sample positions being an even-numbered row of sample positions;
wherein the first group of sample positions and second group of sample positions are spaced such that a gap between the first group of sample positions and second group of sample positions is greater than the first row spacing, and the gap between the first group of sample positions and second group of sample positions is greater than the second row spacing;
a shadow mask comprising a stacked array of hexagonal apertures comprising a series of alternating first sections having decreasing aperture width and second sections having increasing aperture width, wherein the first sections are aligned with odd-numbered rows of sample positions and the second sections are aligned with even-numbered rows of sample positions.

Although different embodiments and groups of embodiments may be disclosed separately in the detailed description which follows, any feature of any embodiment or group of embodiments may be combined with any other feature or combination of features of any embodiment or group of embodiments. That is, all possible combinations and permutations of features disclosed in the present disclosure are envisaged.

### BRIEF DESCRIPTION OF THE DRAWINGS

Specific embodiments are described by way of example only with reference to the following figures:

FIG. 1 is a schematic showing a reflective SLM producing a holographic reconstruction on a screen;

FIG. 2 shows a perspective view of a pair of wavefront replicators arranged for replication in two dimensions;

FIG. 3 shows a cross-sectional schematic view of a first waveguide according to the present disclosure;

FIG. 4 shows a close-up cross-sectional schematic view of a portion of the first waveguide of FIG. 3;

FIG. 5 shows a graph of the ideal increasing transmissivity of a waveguide in the direction of waveguiding;

FIG. 6 show a cross-sectional schematic of a portion of an apparatus for manufacturing a waveguide according to the present disclosure in which a waveguide substrate is passing under a source of dielectric material;

FIG. 7 shows an example coating device in accordance with a comparative example;

FIG. 8A shows a gradient shadow mask in accordance with a comparative example;

FIG. 8B shows a measured thickness of coating material produced with the gradient shadow mask of FIG. 8A;

FIG. 9A shows a hexagonal shadow mask aperture in accordance with the present disclosure;

FIG. 9B shows measured thickness of coating material produced with the shadow mask of FIG. 9A;

FIG. 10A shows a comparative example shadow mask used in conjunction with a sample carrier loaded with samples arranged in a grid layout, the shadow mask applying a gradient coating to a subset of the samples;

FIG. 10B shows single layer reflection spectrum measurements at a plurality of positions on the sample carrier of FIG. 10A;

FIG. 11 shows a tiled/periodic shadow mask in accordance with the present disclosure;

FIG. 12 shows a schematic of a coating device having a plurality of samples aligned with a shadow mask in a configuration according to the present disclosure;

FIG. 13 shows a schematic of the coating device of FIG. 12 having a modified shadow mask;

FIG. 14 shows a schematic of the coating device of FIG. 13 having a modified shadow mask with bridging links;

FIG. 15 shows a schematic of a coating device having the shadow mask of FIG. 12 and a plurality of larger samples arranged on a sample carrier; and

FIG. 16 shows a schematic of the sample carrier of FIG. 15 in combination with the shadow mask of FIG. 13.

The same reference numbers will be used throughout the drawings to refer to the same or like parts.

### DETAILED DESCRIPTION OF EMBODIMENTS

The present invention is not restricted to the embodiments described in the following but extends to the full scope of the appended claims. That is, the present invention may be embodied in different forms and should not be construed as limited to the described embodiments, which are set out for the purpose of illustration.

Terms of a singular form may include plural forms unless specified otherwise.

A structure described as being formed at an upper portion/lower portion of another structure or on/under the other structure should be construed as including a case where the structures contact each other and, moreover, a case where a third structure is disposed there between.

In describing a time relationship—for example, when the temporal order of events is described as “after”, “subsequent”, “next”, “before” or suchlike—the present disclosure should be taken to include continuous and non-continuous events unless otherwise specified. For example, the description should be taken to include a case which is not continuous unless wording such as “just”, “immediate” or “direct” is used.

Although the terms “first”, “second”, etc. may be used herein to describe various elements, these elements are not to be limited by these terms. These terms are only used to distinguish one element from another. For example, a first element could be termed a second element, and, similarly, a second element could be termed a first element, without departing from the scope of the appended claims.

Features of different embodiments may be partially or overall coupled to or combined with each other, and may be variously inter-operated with each other. Some embodiments may be carried out independently from each other, or may be carried out together in co-dependent relationship.

### Conventional Optical Configuration for Holographic Projection

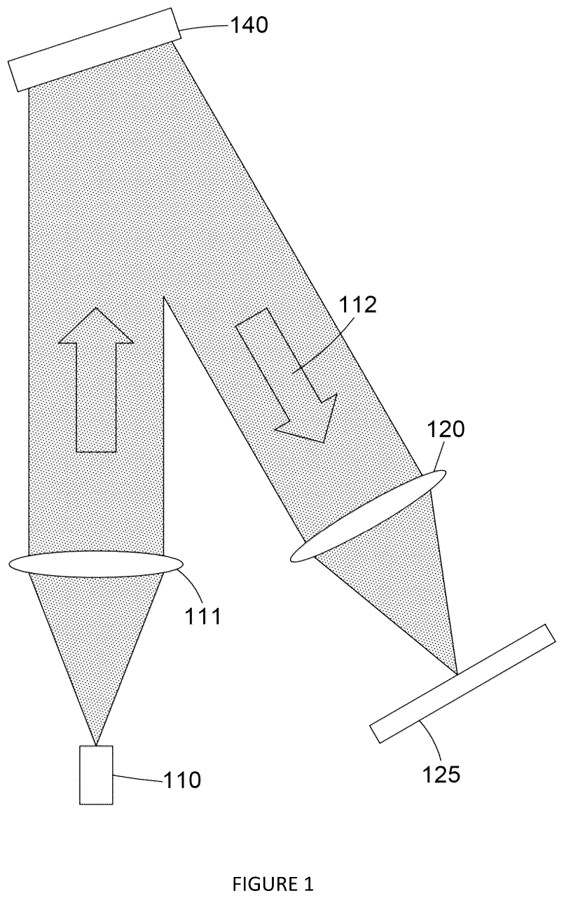

FIG. 1 shows an embodiment in which a computer-generated hologram is encoded on a single spatial light modulator. The computer-generated hologram is a Fourier transform of the object for reconstruction. It may therefore be said that the hologram is a Fourier domain or frequency domain or spectral domain representation of the object. In this embodiment, the spatial light modulator is a reflective liquid crystal on silicon, “LCOS”, device. The hologram is encoded on the spatial light modulator and a holographic reconstruction is formed at a replay field, for example, a light receiving surface such as a screen or diffuser.

A light source 110, for example a laser or laser diode, is disposed to illuminate the SLM 140 via a collimating lens 111. The collimating lens causes a generally planar wavefront of light to be incident on the SLM. In FIG. 1, the direction of the wavefront is off-normal (e.g. two or three degrees away from being truly orthogonal to the plane of the transparent layer). However, in other embodiments, the generally planar wavefront is provided at normal incidence and a beam splitter arrangement is used to separate the input and output optical paths. In the embodiment shown in FIG. 1, the arrangement is such that light from the light source is reflected off a mirrored rear surface of the SLM and interacts with a light-modulating layer to form an exit wavefront 112. The exit wavefront 112 is applied to optics including a Fourier transform lens 120, having its focus at a screen 125. More specifically, the Fourier transform lens 120 receives a beam of modulated light from the SLM 140 and performs a frequency-space transformation to produce a holographic reconstruction at the screen 125.

Notably, in this type of holography, each pixel of the hologram contributes to the whole reconstruction. There is not a one-to-one correlation between specific points (or image pixels) on the replay field and specific light-modulating elements (or hologram pixels). In other words, modulated light exiting the light-modulating layer is distributed across the replay field.

In these embodiments, the position of the holographic reconstruction in space is determined by the dioptric (focusing) power of the Fourier transform lens. In the embodiment shown in FIG. 1, the Fourier transform lens is a physical lens. That is, the Fourier transform lens is an optical Fourier transform lens and the Fourier transform is performed optically. Any lens can act as a Fourier transform lens but the performance of the lens will limit the accuracy of the Fourier transform it performs. The skilled person understands how to use a lens to perform an optical Fourier transform.

In the example of FIG. 1, an image is formed on a screen 125 by holographic reconstruction or transformation. The image may be replicated by a waveguide of the present disclosure. In this example, the waveguide receives, and replicates, a wavefront comprising spatially modulated light in accordance an image. In other examples of the present disclosure, an image is not formed on a screen and instead the hologram is propagated directly to the viewer. This may be described as hologram-to-eye and, at least conceptually, it may be said that the lens of the viewer's eye performs the hologram to image transformation. In these examples, it may be said that the waveguide receives, and replicates, a wavefront comprising spatially modulated light in accordance with a hologram of an image.

### Hologram Calculation

In some embodiments, the computer-generated hologram is a Fourier transform hologram, or simply a Fourier hologram or Fourier-based hologram, in which an image is reconstructed in the far field by utilising the Fourier transforming properties of a positive lens. The Fourier hologram is calculated by Fourier transforming the desired light field in the replay plane back to the lens plane. Computer-generated Fourier holograms may be calculated using Fourier transforms. Embodiments relate to Fourier holography and Gerchberg-Saxton type algorithms by way of example only. The present disclosure is equally applicable to Fresnel holography and Fresnel holograms which may be calculated by a similar method. In some embodiments, the hologram is a phase or phase-only hologram. However, the present disclosure is also applicable to holograms calculated by other techniques such as those based on point cloud methods.

In some embodiments, the hologram engine is arranged to exclude from the hologram calculation the contribution of light blocked by a limiting aperture of the display system. British patent application 2101666.2, filed 5 Feb. 2021 and incorporated herein by reference, discloses a first hologram calculation method in which eye-tracking and ray tracing are used to identify a sub-area of the display device for calculation of a point cloud hologram which eliminates ghost images. The sub-area of the display device corresponds with the aperture, of the present disclosure, and is used exclude light paths from the hologram calculation. British patent application 2112213.0, filed 26 Aug. 2021 and incorporated herein by reference, discloses a second method based on a modified Gerchberg-Saxton type algorithm which includes steps of light field cropping in accordance with pupils of the optical system during hologram calculation. The cropping of the light field corresponds with the determination of a limiting aperture of the present disclosure. British patent application 2118911.3, filed 23 Dec. 2021 and also incorporated herein by reference, discloses a third method of calculating a hologram which includes a step of determining a region of a so-called extended modulator formed by a hologram replicator. The region of the extended modulator is also an aperture in accordance with this disclosure.

In some embodiments, there is provided a real-time engine arranged to receive image data and calculate holograms in real-time using the algorithm. In some embodiments, the image data is a video comprising a sequence of image frames. In other embodiments, the holograms are pre-calculated, stored in computer memory and recalled as needed for display on a SLM. That is, in some embodiments, there is provided a repository of predetermined holograms.

### Two-Dimensional Pupil Expansion or Wavefront Replication

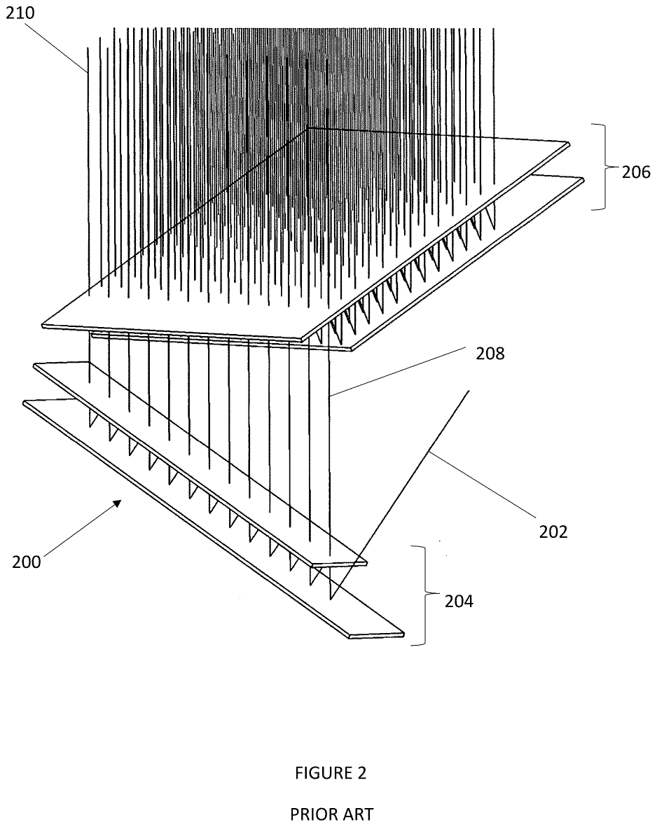

FIG. 2 shows a perspective view of a system 200 comprising two pupil expanders or replicators, 204, 206 arranged for expanding a pupil or replicating a wavefront 202 in two dimensions.

In the system 200 of FIG. 2, the first replicator 204 comprises a first pair of surfaces, stacked parallel to one another, and arranged to provide replication—or, pupil expansion The first pair of surfaces are similarly (in some cases, identically) sized and shaped to one another and are substantially elongate in one direction. The wavefront 202 is directed towards an input on the first replicator 204. The wavefront comprises spatially modulated light in an accordance with an image or a hologram of the image. Due to a process of internal reflection between the two surfaces, and partial transmission of light from each of a plurality of output points on one of the surfaces (the upper surface, as shown in FIG. 2), which will be familiar to the skilled reader, light of the wavefront 202 is replicated in a first direction, along the length of the first replicator 204. Thus, a first plurality of replica wavefronts 208 is emitted from the first replicator 204, towards the second replicator 206.

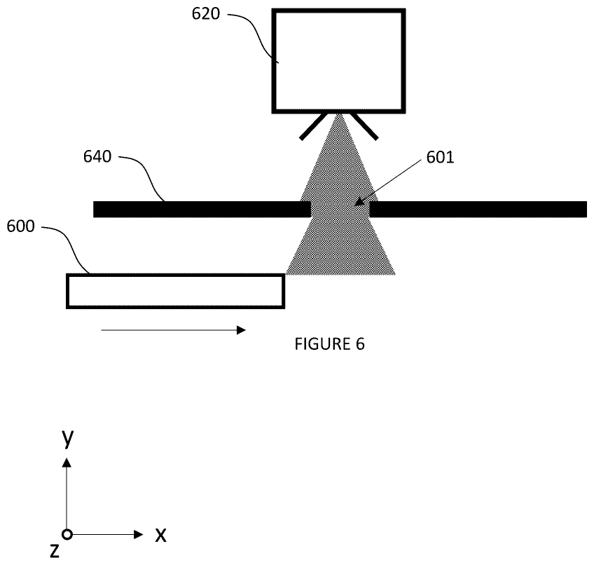

The second replicator 206 comprises a second pair of surfaces stacked parallel to one another, arranged to receive each of the collimated light beams of the first plurality of wavefronts 208 and further arranged to provide replication, or pupil expansion, by expanding each of those light beams in a second direction, substantially orthogonal to the first direction. The first pair of surfaces are similarly (in some cases, identically) sized and shaped to one another and are substantially rectangular. The rectangular shape is implemented for the second replicator in order for it to have length along the first direction, in order to receive the first plurality of wavefronts 208, and to have length along the second, orthogonal direction, in order to provide replication in that second direction. Due to a process of internal reflection between the two surfaces, and partial transmission of light from each of a plurality of output points on one of the surfaces (the upper surface, as shown in FIG. 6), light of each light beam within the first plurality of wavefronts 208 is replicated in the second direction. Thus, a second plurality of wavefronts 210 is emitted from the second replicator 206, wherein the second plurality of wavefronts 210 comprises replicas of the wavefront 202 along each of the first direction and the second direction. Thus, the second plurality of wavefronts 210 may be regarded as comprising a two-dimensional grid, or array, of replica wavefronts. Thus, it can be said that the first and second replicators 204, 205 of FIG. 2 combine to provide a two-dimensional replicator (or, “two-dimensional pupil expander”).

### Improved Waveguide

As described in relation to FIG. 2, light in the waveguide is reflected between a partially reflective, partially transmissive surface and a reflective surface of a waveguide. Light may undergo one or more reflections or bounces between the two reflective/reflective-transmissive planar surfaces and, at each bounce point on the partially transmissive surface, the light is divided such that a portion of the light is emitted out of the waveguide and the remaining (typically larger) portion of the light is reflected to continue to propagate between the two surfaces of the waveguide. This effectively results in the partially transmissive surface of the waveguide providing a plurality, n, of light emission zones for light waveguided between the first surface and second surface. After each bounce point/emission zone, the intensity of the light propagating in the waveguide will decrease. In other words, the intensity of the light propagating in the waveguide decreases in the direction of waveguiding.

It is desirable for the intensity of the light emitted out of the waveguide at each of the n light emission zones to be substantially the same. This can be achieved this by providing an improved waveguide in which a layered coating is provided on the partially transmissive surface of the waveguide to cause the transmissivity of the partially transmissive surface to decrease in the direction of waveguiding. This accounts for the decrease in the intensity of the propagating light in the direction of waveguiding.

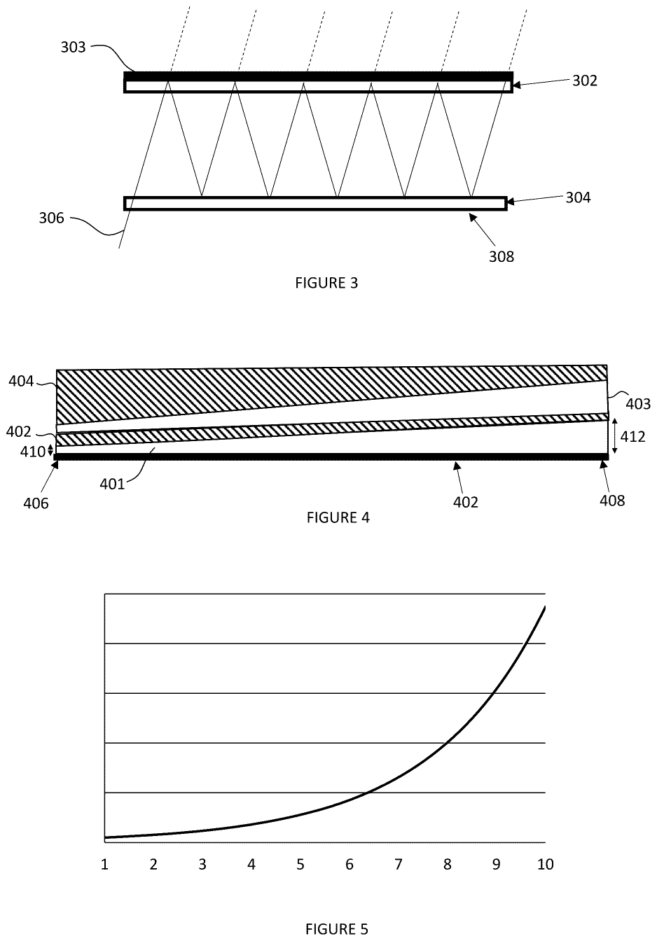

FIG. 3 is schematic cross-sectional view of a waveguide 308 according to the disclosure. The waveguide 308 comprises a first surface 302 and a second surface 304. A light field or wavefront 306 (represented by one light ray in FIG. 3) is shown propagating through the waveguide 308. The second surface 304 comprises an input port arranged to receive the light field. The first surface 302 is partially transmissive, partially reflective and comprises a coating 303. The term “coating” is merely used herein for convenience and the person skilled in the art will appreciate that components described as a “coating” may be formed by any method including, but not limited to, a coating process. The second surface 304 is substantially fully reflective (other than at the input). FIG. 3 shows the path of the light field or wavefront through the waveguide, bouncing between the first and second surfaces. On each reflection at the first surface, the light field divides such that a portion of the light field is emitted through the first surface and a remaining portion is reflected and continues to propagate between the first and second surfaces by reflection. So, an emission zone is effectively formed at each reflection point. FIG. 3 shows six emission zones, however the skilled person will understand that there could, of course, be a larger or smaller number of reflections and emission zones. FIG. 3 is merely illustrative.

In some embodiments, the coating 303 comprises a plurality of layers of a first dielectric and a plurality of layers of a second dielectric in an alternating configuration. This is illustrated in FIG. 4. The layers of the coating will be referred to herein by number, with the layer in contact with the first surface 302 being the first layer (layer 401). Layer 402 is on top of layer 401 and layer 403 is on top of layer 402. The layer furthest from the first surface 302, which is in top of layer 403, is the fourth layer 404. In this example, layers 401 and 403 are formed of silicon dioxide (SiO2) and layers 402 and 404 are formed of titanium dioxide (TiO2) such that the layers are in an alternating configuration in which subsequent layers of SiO2 (the first dielectric) are separated by layers of TiO2 (the second dielectric).

Each of layers 401 to 404 has a varying thickness in the direction of waveguiding (from left to right in FIG. 4) and, in this embodiment by way of example, has a linear profile. In other words, the rate of change of thickness of each layer is constant. The profile of each layer can be characterized using a percentage change in thickness. Each layer has a first end 406 and a second end 408. The percentage change in thickness is defined as the change in thickness from the first end 906 to the second end 408 divided by the thickness at the first end 406 multiplied by 100. For the case of the first layer 401, the percentage change in thickness is 100×(final thickness 412−initial thickness 410)/initial thickness 410.

Layer 403 has the same percentage change in thickness as layer 401. Furthermore, the percentage change value is positive for both layers 401 and 403 (i.e. the thickness of the layer increases from the first end 406 to the second end 408). Layer 402 and 404 both have different percentage changes to one another and to layers 401 and 403. Furthermore, both the percentage change of layers 402 and 404 is negative (i.e. the thickness of the layers decreases from the first end 406 to the second end 408).

It has been found that by, selecting an appropriate number of alternating layers of the first and second dielectric, with the layers having an appropriate thickness and percentage change in thickness from the first end to the second end, a first surface of the waveguide can be provided having a transmissivity that increases in the direction of waveguiding. In this way, the intensity of the light field emitted at each emission zone (i.e. the intensity of each replica emitted at each emission zone) is substantially constant. This may advantageously achieve a substantially spatially homogeneous emission of light from the waveguide.

An ideal exponential increase of the transmissivity of the first surface 302 is shown in FIG. 5 which is a graph showing transmissivity on the Y axis and position along the first surface 302 on the X axis. The numbers on the X axis represent the n emission zone. Specifically, the transmissivity increases according to the following equation:

$$T ( n ) = \frac{T ( n - 1 )}{[ 1 - T ( n - 1 ) ] \times [ 1 - L ]}$$

where L is the optical loss factor of the waveguide material.

### Method of Manufacture

FIG. 6 is a schematic cross-sectional view of a portion of the apparatus for manufacturing a waveguide according to the present disclosure, the cross-section being in X-Y plane. The portion of the apparatus shown in FIG. 6 comprises a first source of SiO₂ and a shadow mask 640 comprising a first aperture 601. A waveguide substrate 600 (in the form of a glass or Perspex block or slab) is also shown. SiO2 material is configured to flow out of the first source 620 and through the first aperture 601 of the shadow mask 640. The flow of material is in the negative Y direction. The shape of the first aperture 601 determines the shape of the flow SiO2 downstream of the shadow mask 640. FIG. 6 is not drawn to scale.

The means to move the waveguide substrate 600 (not shown in drawings) is arranged to move the waveguide substrate 600 in a first plane that is perpendicular to the Y direction such that the waveguide substrate 600 passes under the first aperture 601. In some embodiments, the motion is entirely in the X direction. However, in other embodiments the waveguide substrate 600 may be rotated in the first plane such that the motion is in both an X direction and a Z direction.

In FIG. 6, the waveguide substrate 600 has yet to pass under the first aperture 601 and so no coating layer is present on the waveguide substrate 600. As the waveguide substrate passes under the first aperture 601 (in the X direction), dielectric coating is deposited on the substrate. Generally, in order to manufacture a complete layer, the waveguide substrate 600 will need to pass under the first aperture 601 multiple times until the desired thickness is achieved.

Once the first layer has been formed, the waveguide substrate 600 will be moved under one of the sources of second dielectric material such that a second layer of (of second dielectric material) is formed on top of the first layer of first dielectric material.

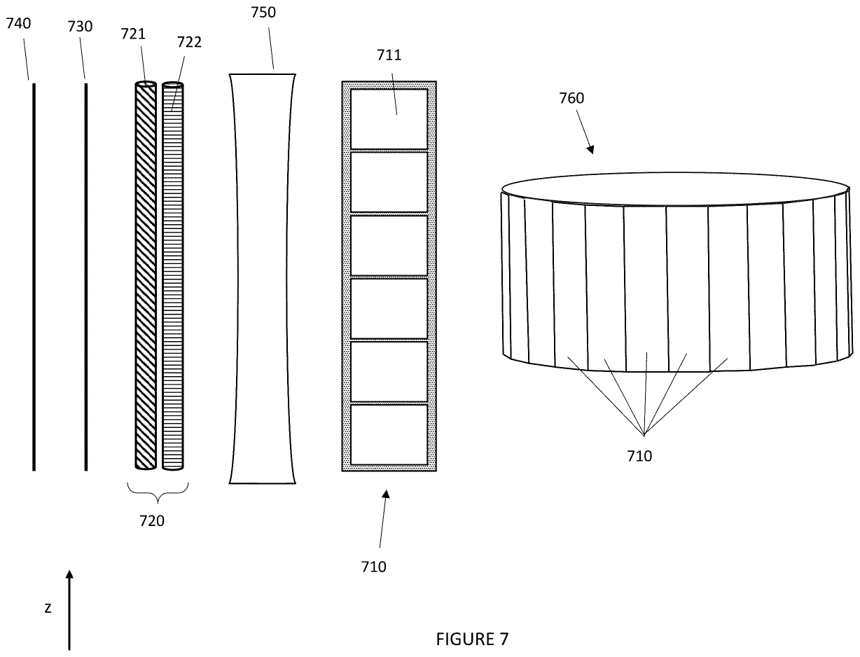

FIG. 7 represents a coating chamber for a comparative example coating device. FIG. 7 shows a sample carrier 1010 comprises a plurality of individual samples such as first sample 711. FIG. 7 shows a dual rotary source 720 comprising a first target 721 and second target 722. FIG. 7 further shows a gas control 730 which provides ten adjustment positions along the full length and a remotely adjustable magnetic, “RAM”, bar 740 which also provides ten adjustment positions along its full length. A shadow mask 750 is aligned with the targets 721, 722. In this drawing, the shadow mask 750 has an arc shape designed to maximise the uniformity of the coating thickness, such that each of the samples 711 has an even thickness of coating material across the entire surface of the sample 711.

In a first example, a RAM bar 740 directly changes a magnetic field of the coating process. For example, the coating process may comprise sputtering such as magnetron sputtering. There is a plurality of adjustable positions or drive or operation levels—such as ten adjustment positions—in the full length which is not enough to provide an adequate gradient in e.g. six samples. The feature is typically provided to facilitate the formation of uniform rather than gradient thickness coatings. In other words, this feature is provided for uniformity adjustment.

In a second example, the gas pressure inside the chamber is adjusted. In some embodiments, the gas is argon and Art ions bombard the target/s to cause eject of coating material towards the sample carrier. The gas control 730 has a plurality of adjustable positions or drive or operation levels—such as five or ten adjustable positions—which is also not enough to provide an adequate gradient in e.g. six slabs but is good for the formation of uniform coatings and uniformity adjustment. The feature is typically provided to facilitate the formation of uniform rather than gradient thickness coatings. In other words, this feature is provided for uniformity adjustment.

In a third example, a slight adjustment of a so-called magnet swing changes the direction of deposition.

These three examples are control parameters in addition to the gradient shadow mask that physically blocking deposition to achieve gradient. The relatively small adjustments of the three examples referred to above are relatively small compared to the impact of the mask. The relatively small adjustments referred to above are achieved by software control rather than hardware control such as changing a mask inside the chamber.

In some embodiments, the dual rotary target is configured to have two different materials. This effectively creates gradient index mix-material in sputtering. Mix-material sputtering is more stable in a single set of dual rotary target than using two physically separated targets. In some embodiments, optical monitoring is also used.

The coating device may also be formed as part of a drum coating machine. For example, as illustrated in FIG. 7, there may be provided a drum 760 with a plurality of sample carriers 710 arranged around the circumference of the drum 760. The targets 720 may be arranged at the centre of the drum 760. The drum 760 may be rotated at a controlled speed to deposit the coating material onto the samples 711.

The inventors have discovered and developed a coating device and method that modifies such an existing coating machine architecture to allow for graded coatings to be applied to samples with a desired gradient by incorporating a periodic shadow mask.

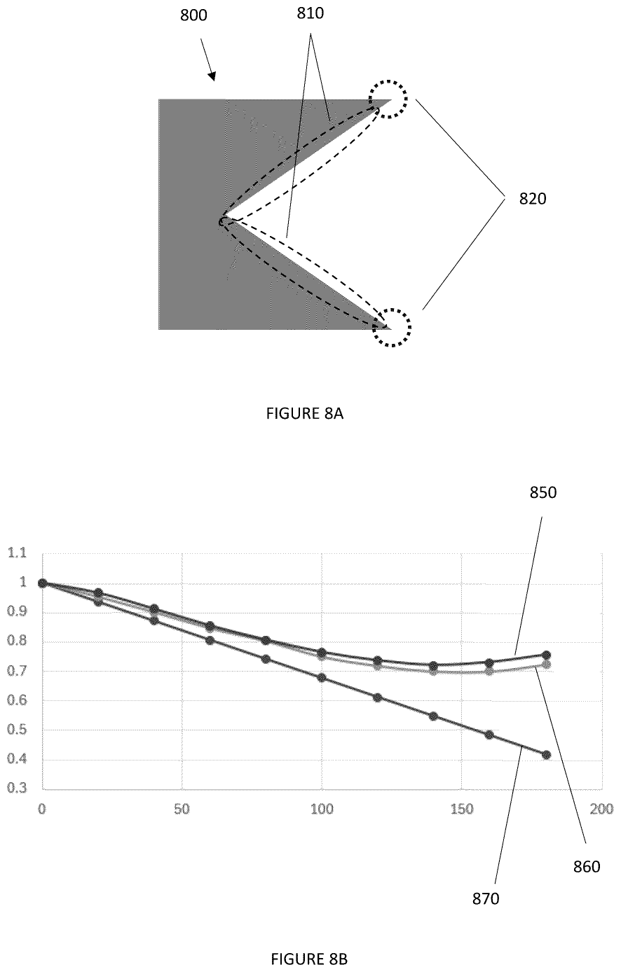

FIG. 8A illustrates a gradient shadow mask 800 of a comparative example. The gradient shadow mask 800 is arranged such that each of the sloped edges 810 is aligned with a corresponding sample (e.g. 711 of FIG. 7) in order to provide a gradient of coating material to a sample. In other words, only one sloped edge of the shadow mask 800 contributes to the gradient coating. The gradient shadow mask 800 therefore comprises corners 820 where the shape of the shadow mask 800 changes direction. The inventors have identified that this type of gradient shadow mask causes unwanted defects in the desired coating gradient.

FIG. 8B shows measurement data for two samples coated with a shadow mask 800 as described with respect to FIG. 8A. FIG. 8B shows the measured thickness of the coating as a function of distance along the sample. Plotted line 850 shows the measured thickness as a function of distance along a first sample and plotted line 860 shows the measured thickness as a function of distance along a second sample. Also shown in FIG. 8B is a desired/design coating gradient 870 that can be understood as a target thickness gradient. As is seen from FIG. 8B, the thickness profiles 850 and 860 of the measured samples deviates from the target thickness gradient 870 further along the samples. The inventors identified that a cause of this deviation is due to gas turbulence induced by the relatively sharp corners 820 of the shadow mask 800 and have developed a modified shadow mask to reduce this detrimental effect as described below in accordance with the present disclosure.

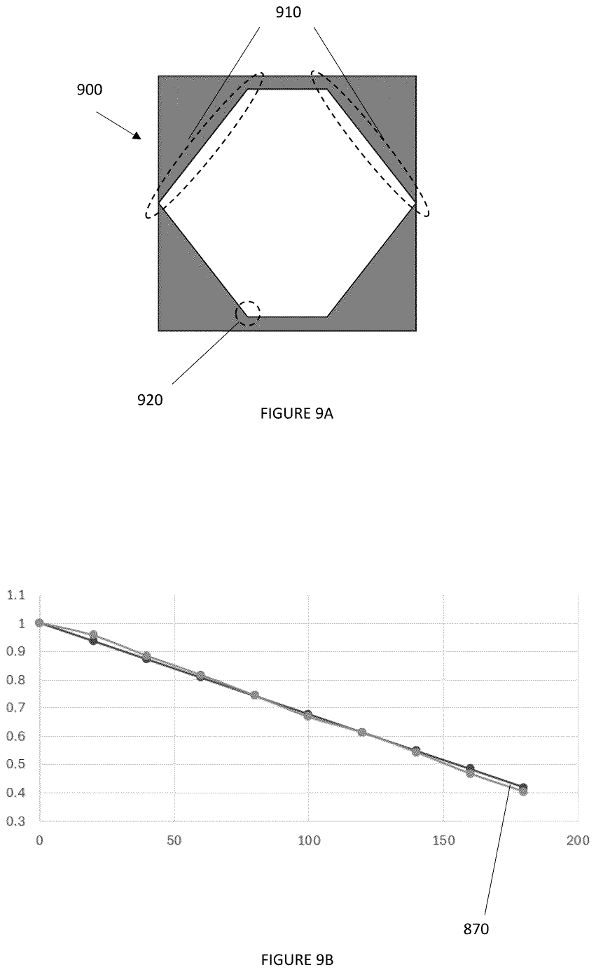

FIG. 9A shows a modified shadow mask 900 according to the present disclosure. The shadow mask 900 comprises two angled edges 910 that both contribute to applying a gradient coating to a set of samples. Likewise, the lower two angled edges of the shadow mask 900 both contribute to applying a gradient coating to another set of samples. Since two edges of the shadow mask contribute to the gradient coating rather than just one edge (as in FIG. 8A), the slope of each edge can be shallower. The inventors have found that this shallower angle helps to improve the gas turbulence issue identified above. Additionally, the internal angles (e.g. angle 920) of the shadow mask aperture are less abrupt in the shadow mask 900, thus also resulting in a reduction in gas turbulence. The aperture of the shadow mask can therefore be considered as a hexagonal opening, with the top half (as shown in FIG. 9A) providing one gradient coating and the bottom half providing another gradient coating contribution.

FIG. 9B corresponds to the same type of plot as that of FIG. 8B, but with coatings provided by the shadow mask 900 of FIG. 9A. As can be seen, the measured coating thicknesses obtained from modified shadow mask 900 are much closer to the desired/target thickness gradient 870, and therefore provides a marked improvement in gradient coating accuracy.

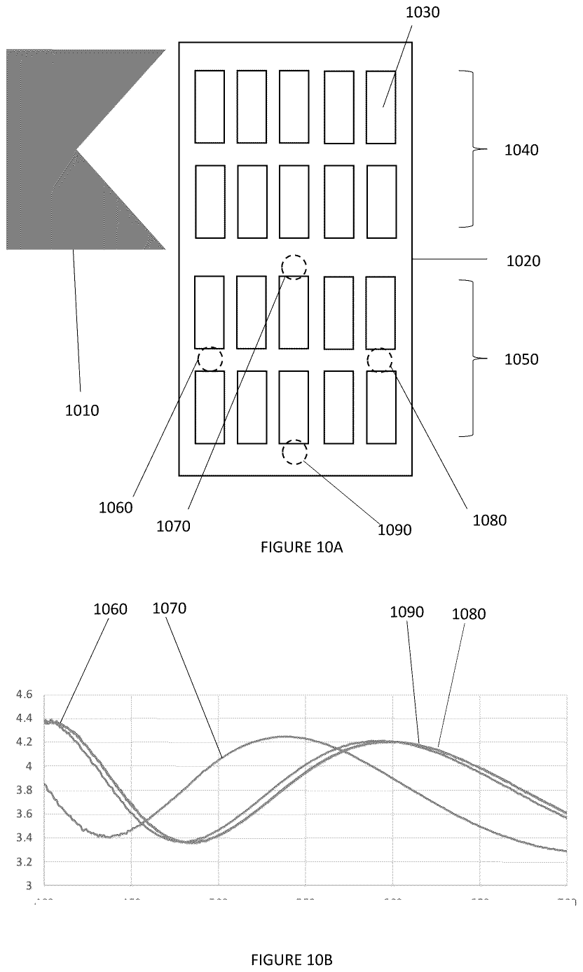

Another avenue of improvement identified by the inventors is the effect of interference introduced when samples are arranged in a tiled format on the sample carrier. FIG. 10A shows a shadow mask 1010 (corresponding to the shadow mask 800 of FIG. 8A) used in conjunction with a sample carrier 1020 loaded with a plurality of samples 1030 arranged in a grid layout. The shadow mask 1010 is arranged to provide a gradient coating to a first subset of samples 1040, while a second subset of samples 1050 does not have a corresponding shadow mask. To investigate the effect of the shadow mask 1010 on an adjacent set of samples (i.e. second subset 1050), a single layer reflection spectrum was measured at a number of different locations 1060, 1070, 1080, 1090 surrounding the second subset 1050 of samples.

FIG. 10B shows the result of the single layer reflection spectrum measurements at each corresponding measurement location. As can be seen, the refection spectrum measured at location 1070 significantly deviates from the spectrum measured at the other locations (which are approximately equal to one another). The inventors recognised that this deviation results from an interference effect from the presence of the shadow mask 1010 arranged to coat the first subset 1040 of samples. Therefore, according to the present disclosure a minimum clearance is provided between subsets/groups of samples to avoid/reduce the effect of interference from an adjacent portion of shadow mask. For example, a spacing between subsets/groups of samples may be twice the spacing between rows of samples within a subset/group of samples, as discussed herein.

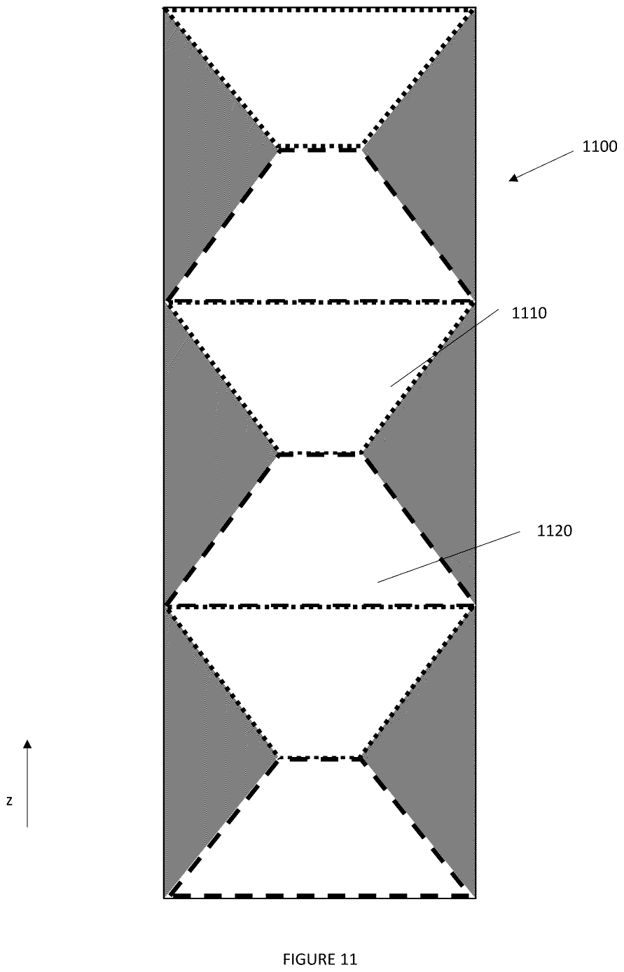

FIG. 11 shows a tiled/periodic shadow mask 1100 in accordance with embodiments of the present disclosure. The periodic shadow mask 1100 comprises alternating first components 1110 and second components 1120 in a repeating pattern. Each of first and second components 1110, 1120 may be substantially trapezoidal in shape, and may also be substantially identical to one another, but flipped in the horizontal direction (otherwise referred to herein as the second dimension/direction). The first and second components 1110, 1120 may tile in a back-to-back configuration so as to effectively provide a continuous aperture in the shadow mask 1100. This continuous aperture can therefore be viewed as a series of conjoined hexagonal apertures (e.g. a tiled series of hexagonal apertures illustrated in FIG. 9A). Each first component 1110 may comprise an increase in aperture size in a horizontal direction (second dimension) of the figure when progressing along the z axis (first dimension). Each second component 1120 may comprise a decrease in aperture size in a horizontal direction (second dimension) of the figure when progressing along the z axis (first dimension).

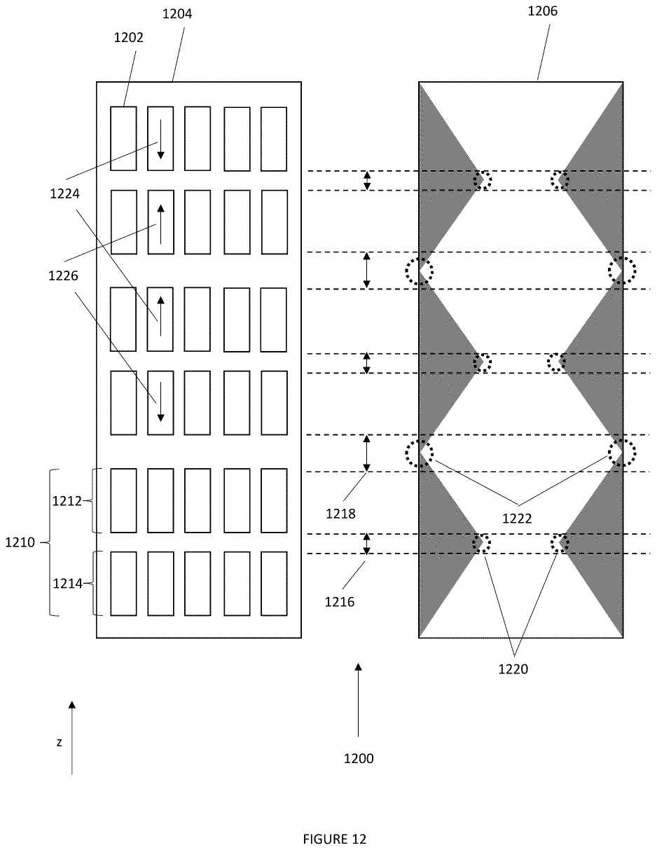

The first components 1110 and second components 1120 of the shadow mask 1100 may each be aligned with a respective row of samples (not shown) as described below with reference to FIGS. 12-16.

FIG. 12 shows a coating device 1200 comprising a plurality of samples 1202 arranged on a sample carrier 1204 with a shadow mask 1206 positioned to apply a gradient coating to the samples 1202 in accordance with embodiments of the present disclosure.

The plurality of samples 1202 are arranged in a plurality of groups 1210, and each group comprises a first row 1212 of samples and a second row 1214 of samples. The first row 1212 and second row 1214 of each group 1210 are spaced apart on the z axis (first dimension) by a first spacing 1216. Each group 1210 is spaced from each adjacent group 1210 by a second spacing 1218. The first spacing 1216 is smaller than the second spacing 1218.

In the embodiment of FIG. 12, each first row 1212 is aligned with a corresponding component of the shadow mask 1206. In this embodiment, each first row is aligned with a first aperture component 1110 (as defined in FIG. 11). Likewise, each second row 1214 is aligned with a corresponding second aperture component 1120.

Each first spacing 1216 is aligned with corresponding first corners 1220 (otherwise referred to as a gradient transition) of the shadow mask 1206. These first corners 1220 may be rounded in accordance with embodiments of the disclosure. The first corners 1220 have a first radius of curvature. The first radius of curvature is smaller than the respective first spacing 1216.

Likewise, each second spacing 1218 is aligned with corresponding second corners 1222 of the shadow mask 1206. The second corners 1222 may also be rounded and have a second radius of curvature. The second radius of curvature is smaller than the respective spacing 1218. The second radius of curvature may also be larger than the first radius of curvature.

Each of the plurality of samples may have an orientation with respect to the z axis (first dimension). In accordance with embodiments, each sample of the first rows 1212 may have a first orientation 1224. Each sample of the second rows 1214 may have a second orientation 1226. The first orientation 1224 is opposite to the second orientation 1226. Two possible combinations of orientations are illustrated in FIG. 12. In other words, the samples or sample positions may be asymmetrical (either in terms of their geometry or another physical (e.g. optical) property) about an axis parallel to the second dimension. In this way, such asymmetrical samples in two different rows may have the same gradient of coating applied to them since the aperture gradient of the first component of the shadow mask (aligned with a first row having a first orientation) may be opposite to that of the second component of the shadow mask (aligned with a second row having a second orientation opposite the first orientation).

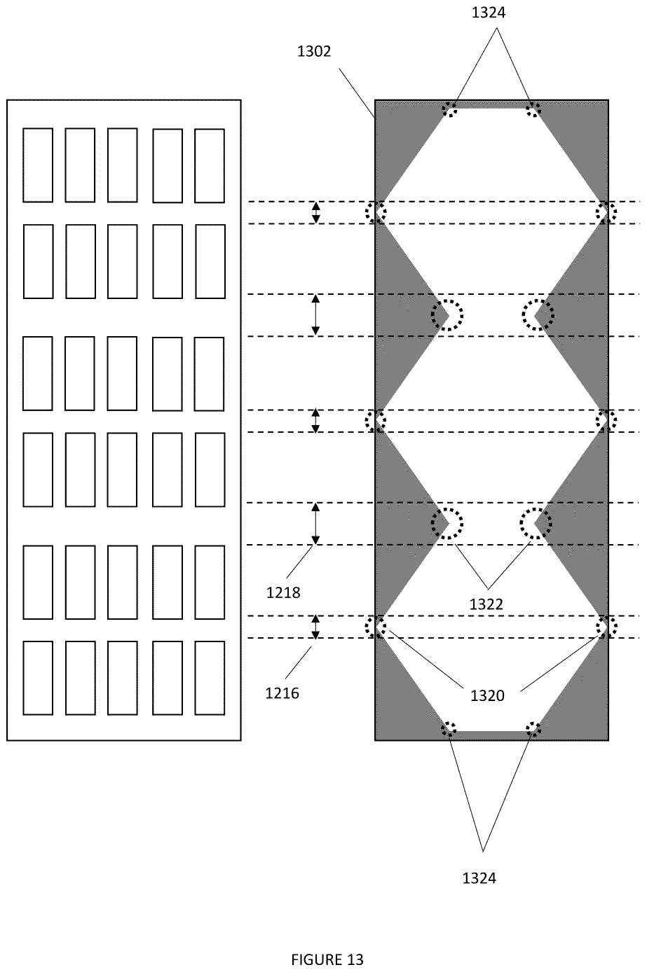

FIG. 13 shows a coating device substantially corresponding to that of FIG. 12, but with a differently configured shadow mask 1302. In the arrangement of FIG. 13, the first rows 1212 are each aligned with a second aperture component 1120 rather than a first aperture component 1110 as in FIG. 12. Therefore, the direction of thickness gradient applied across the rows of samples may be reversed compared to the arrangement of FIG. 12. This may be achieved, for example, by shifting/translating the shadow mask 1206 along the z axis, or by providing a different shadow mask.

The same principles of spacings and rounded corner radii of curvature apply. That is, the first spacings 1216 are aligned with first corners 1320 and second spacings 1218 are aligned with second corners 1322. The first spacings 1216 are smaller than the second spacings 1218. The radii of curvature for the first corners 1320 are smaller than the radii of curvature for the second corners 1322.

As further illustrated in FIG. 13, the distal ends of the shadow mask may be closed off to avoid abrupt/sharp angles on the shadow mask. This may result in additional corners 1324 at either end of the shadow mask 1302 which may also be rounded.

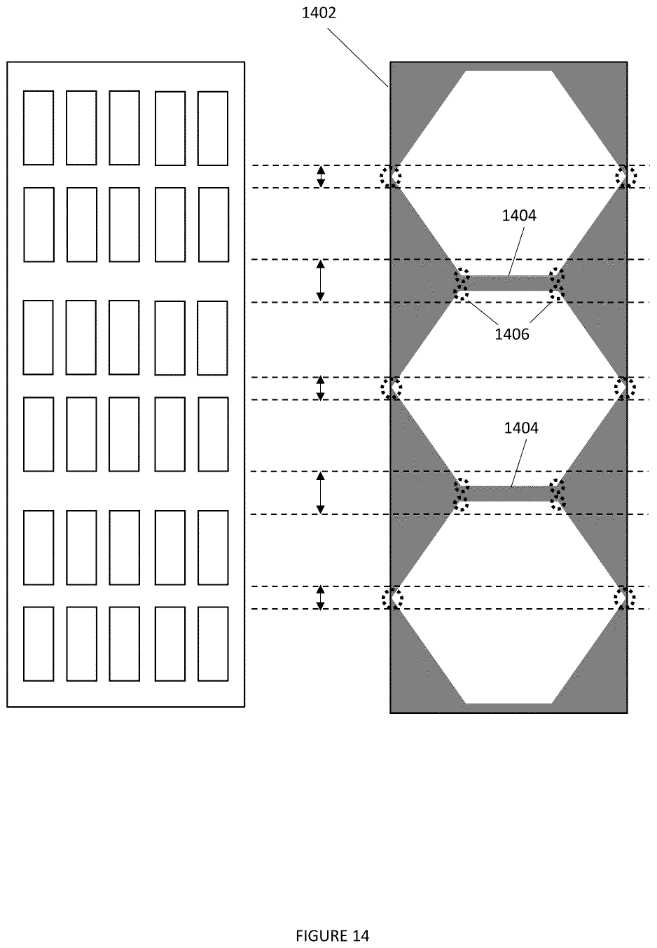

FIG. 14 shows a shadow mask 1402 substantially corresponding to the shadow mask 1302 of FIG. 13 but with additional bridging links 1404. The bridging links 1404 effectively replace the second corners 1322 in the arrangement of FIG. 13. These bridging links 1404 connect opposite sides of the shadow mask 1402 where the aperture is narrowed and act to further reduce the presence of abrupt/sharp angles, thus reducing the effect of gas turbulence on the deposition of coating material.

The inclusion of bridging links 1404 results in additional “bridging corners” 1406 formed at the intersection of the bridging links 1404 and the angled edges of the first and second aperture components 1110, 1112. These bridging corners 1406 may also be rounded with a radius of curvature smaller than the distance between the bridging link 1404 and the beginning of the respective first row 1212 or second row 1214 of samples (in the z direction).

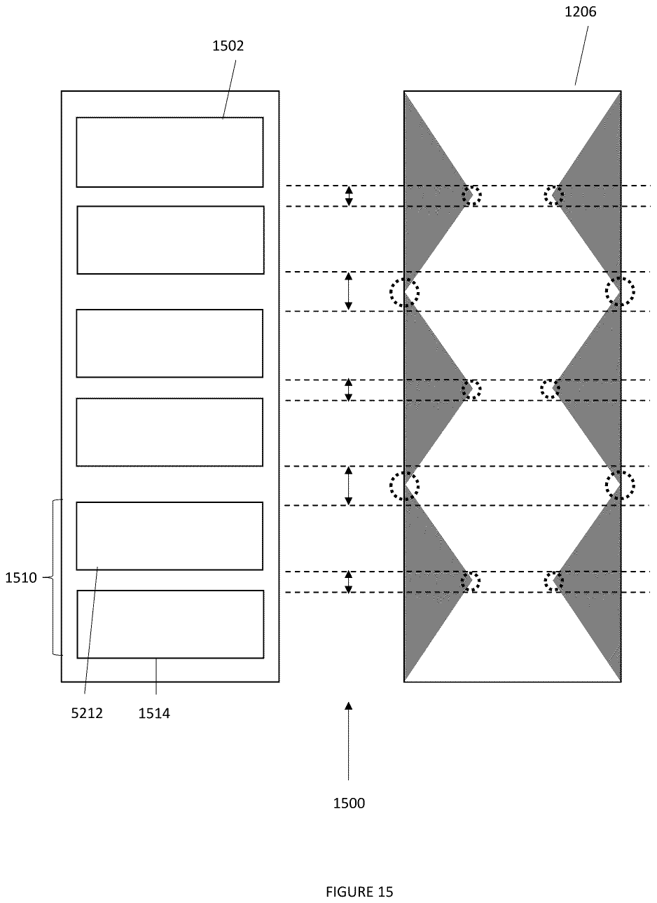

FIG. 15 shows a coating device 1500 with a shadow mask 1206 corresponding to that described above with reference to FIG. 12. The plurality of samples 1502 in this embodiment are arranged such that each first row 1212 and second row 1214 are made up of one larger sample rather than each row comprising a plurality of (smaller) samples. The samples 1502 are, however, still arranged in pairs 1510 comprising a first sample 1512 and a second sample 1514 (corresponding to the first and second rows). As such, the same principles of spacings between pairs of samples 1510 and the respective corners of the shadow mask apply to the coating device 1500 as the coating device 1200.

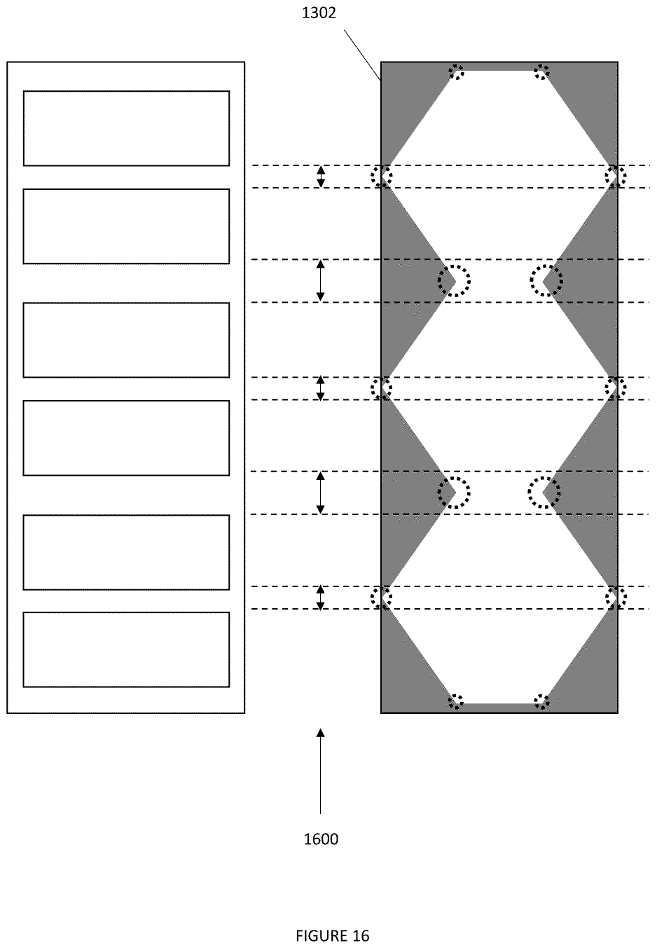

FIG. 16 shows a coating device 1600 with a sample 1502 layout corresponding to that of FIG. 15, but with a shadow mask 1302 corresponding to that of FIG. 13. The shadow mask 1302 of FIG. 16 can therefore be understood as applying coatings in an opposite direction to that of FIG. 15.

It is additionally noted that the bridging links 1404 may be omitted in certain embodiments when using larger samples 1502 when a shallower gradient shadow mask is used, since a shallower gradient is less disruptive the coating material as it is deposited onto the samples since the shallower gradient produces less gas turbulence. A ratio of second spacings between pairs of samples to first spacings may be larger in these embodiments. For example, the second spacings may be approximately 3 times larger than the first spacings.

### ADDITIONAL FEATURES

The methods and processes described herein may be embodied on a computer-readable medium. The term “computer-readable medium” includes a medium arranged to store data temporarily or permanently such as random-access memory (RAM), read-only memory (ROM), buffer memory, flash memory, and cache memory. The term “computer-readable medium” shall also be taken to include any medium, or combination of multiple media, that is capable of storing instructions for execution by a machine such that the instructions, when executed by one or more processors, cause the machine to perform any one or more of the methodologies described herein, in whole or in part.

The term “computer-readable medium” also encompasses cloud-based storage systems. The term “computer-readable medium” includes, but is not limited to, one or more tangible and non-transitory data repositories (e.g., data volumes) in the example form of a solid-state memory chip, an optical disc, a magnetic disc, or any suitable combination thereof. In some example embodiments, the instructions for execution may be communicated by a carrier medium. Examples of such a carrier medium include a transient medium (e.g., a propagating signal that communicates instructions).

It will be apparent to those skilled in the art that various modifications and variations can be made without departing from the scope of the appended claims. The present disclosure covers all modifications and variations within the scope of the appended claims and their equivalents.

What is claimed is:

1. A method of coating a plurality of waveguides for head-up display, the method comprising:
forming a first group of waveguides by:
arranging a first row of one or more first waveguides in a first orientation, the first row of one or more first waveguides being an odd-numbered row of waveguides; and
arranging a second row of one or more second waveguides in a second orientation, wherein the second orientation is opposite the first orientation, such that the first row of one or more first waveguides opposes the second row of one or more second waveguides, and such that the first row of one or more first waveguides is spaced apart from the second group of one or more second waveguides by a first row spacing, the second row of one or more second waveguides being an even-numbered row of waveguides;
forming a second group of waveguides by:
arranging a third row of one or more third waveguides in the first orientation, the third row of one or more third waveguides being an odd-numbered row of waveguides; and
arranging a fourth row of one or more fourth waveguides in the second orientation such that the third row of one or more third waveguides opposes the fourth row of one or more fourth waveguides, and such that the third row of one or more third waveguides is spaced apart from the fourth row of one or more fourth waveguides by a second row spacing, the fourth row of one or more fourth waveguides being an even-numbered row of waveguides;
spacing the first group of waveguides and second group of waveguides such that a gap between the first group of waveguides and second group of waveguides is greater than the first row spacing, and the gap between the first group of waveguides and second group of waveguides is greater than the second row spacing; and
coating the first group of waveguides and second group of waveguides through a shadow mask comprising a stacked array of hexagonal apertures comprising a series of alternating first sections having decreasing aperture width and second sections having increasing aperture width, wherein the first sections are aligned with odd-numbered rows of waveguides and the second sections are aligned with even-numbered rows of waveguides.

2. The method of claim 1, wherein the stacked array of hexagonal apertures is arranged such that adjacent hexagonal aperture components directly abut one another.

3. The method of claim 1, wherein the stacked array of hexagonal apertures is arranged such that adjacent hexagonal aperture components are separated by a bridging link of the shadow mask.

4. The method of claim 1, wherein the shadow mask comprises a gradient transition between each of the alternating first sections and second sections, wherein each gradient transition comprises a rounded corner aligned with one of:
(i) the spacing between the first row of one or more first waveguides and the second row of one or more second waveguides;
(ii) the spacing between the third row of one or more third waveguides and the fourth row of one or more fourth waveguides; or
(iii) the gap between the first group of waveguides and the second group of waveguides.

5. The method of claim 4, wherein a radius of curvature of the rounded corners is smaller for rounded corners aligned with (i) the spacing between the first row of one or more first waveguides and the second row of one or more second waveguides and (ii) the spacing between the third row of one or more third waveguides and the fourth row of one or more fourth waveguides, compared to a radius of curvature for rounded corners aligned with (iii) the gap between the first group of waveguides and the second group of waveguides.

6. The method of claim 5, wherein a radius of curvature of the rounded corner is smaller than the respective (i) spacing between the first row of one or more first waveguides and the second row of one or more second waveguides; (ii) spacing between the third row of one or more third waveguides and the fourth row of one or more fourth waveguides; or (iii) gap between the first group of waveguides and the second group of waveguides.

7. The method of claim 6 wherein an angle of the rounded corners is greater than 90 degrees and smaller than 120 degrees.

8. The method of claim 1, wherein each of the alternating first sections of the shadow mask and second sections of the shadow mask are substantially trapezoidal components which abut one another to form the stacked array of hexagonal apertures.

9. The method of claim 1, wherein the step of coating the first group of waveguides and second group of waveguides through the shadow mask comprises:
arranging a source to output a coating material; and
positioning the shadow mask between the source and the first group of waveguides and second group of waveguides.

10. The method of claim 9, wherein the step of coating the first group of waveguides and second group of waveguides through the shadow mask further comprises providing a coating driver arranged to control the source, wherein the coating driver comprises at least one selected from the group comprising: a magnetic bar controller arranged to change the magnitude of a magnetic field at a plurality of positions of the source, a pressure controller arranged to change the pressure of a gas; and a magnet rotator arranged to control a direction of deposition of the coating material.

11. The method of claim 10, further comprising arranging the first group of waveguides and second group of waveguides on a sample carrier, and wherein the step of coating the first group of waveguides and second group of waveguides through the shadow mask further comprises:
configuring a drum to house the sample carrier; and
positioning the source at the centre of the drum, wherein the shadow mask is positioned between the source and the sample carrier, and
rotating the drum at a determined speed in order to coat the first group of waveguides and second group of waveguides with the coating material.

12. A coating device comprising:
a sample carrier;
a plurality of waveguides arranged on the sample carrier in a first group of waveguides and a second group of waveguides,
wherein the first group of waveguides comprises:
a first row of one or more first waveguides arranged in a first orientation, the first row of one or more first waveguides being an odd-numbered row of waveguides; and
a second row of one or more second waveguides arranged in a second orientation, wherein the second orientation is opposite the first orientation, such that the first row of one or more first waveguides opposes the second row of one or more second waveguides, and such that the first row of one or more first waveguides is spaced apart from the second group of one or more second waveguides by a first row spacing, the second row of one or more second waveguides being an even-numbered row of waveguides;
wherein the second group of waveguides comprises:
a third row of one or more third waveguides arranged in the first orientation, the third row of one or more third waveguides being an odd-numbered row of waveguides; and
a fourth row of one or more fourth waveguides arranged in the second orientation such that the third row of one or more third waveguides opposes the fourth row of one or more fourth waveguides, and such that the third row of one or more third waveguides is spaced apart from the fourth row of one or more fourth waveguides by a second row spacing, the fourth row of one or more fourth waveguides being an even-numbered row of waveguides;
wherein the first group of waveguides and second group of waveguides are spaced such that a gap between the first group of waveguides and second group of waveguides is greater than the first row spacing, and the gap between the first group of waveguides and second group of waveguides is greater than the second row spacing;
a source arranged to coat the plurality of waveguides with a coating material; and
a shadow mask positioned between the source and the sample carrier, the shadow mask comprising a stacked array of hexagonal apertures comprising a series of alternating first sections having decreasing aperture width and second sections having increasing aperture width, wherein the first sections are aligned with odd-numbered rows of waveguides and the second sections are aligned with even-numbered rows of waveguide.

13. The coating device of claim 12, wherein the stacked array of hexagonal apertures is arranged such that adjacent hexagonal aperture components directly abut one another.

14. The coating device of claim 12, wherein the stacked array of hexagonal apertures is arranged such that adjacent hexagonal aperture components are separated by a bridging link of the shadow mask.

15. The coating device of claim 12, wherein the shadow mask comprises a gradient transition between each of the alternating first sections and second sections, wherein each gradient transition comprises a rounded corner aligned with one of:
(i) the spacing between the first row of one or more first waveguides and the second row of one or more second waveguides;
(ii) the spacing between the third row of one or more third waveguides and the fourth row of one or more fourth waveguides; or
(iii) the gap between the first group of waveguides and the second group of waveguides.

16. The coating device of claim 15, wherein a radius of curvature of the rounded corners is smaller for rounded corners aligned with (i) the spacing between the first row of one or more first waveguides and the second row of one or more second waveguides and (ii) the spacing between the third row of one or more third waveguides and the fourth row of one or more fourth waveguides, compared to a radius of curvature for rounded corners aligned with (iii) the gap between the first group of waveguides and the second group of waveguides.

17. The coating device of claim 16, wherein a radius of curvature of the rounded corner is smaller than the respective (i) spacing between the first row of one or more first waveguides and the second row of one or more second waveguides; (ii) spacing between the third row of one or more third waveguides and the fourth row of one or more fourth waveguides; or (iii) gap between the first group of waveguides and the second group of waveguides.

18. The coating device of claim 17 wherein an angle of the rounded corners is greater than 90 degrees and smaller than 120 degrees.

19. The coating device of claim 12, wherein each of the alternating first sections of the shadow mask and second sections of the shadow mask are substantially trapezoidal components which abut one another to form the stacked array of hexagonal apertures.

20. The coating device of claim 12, further comprising:
a drum configured to house at least the sample carrier; and
wherein the shadow mask is positioned between the source and the sample carrier,
wherein the drum is configured to rotate at a determined speed in order to coat the plurality of with the coating material.

21. A coating device comprising:
a sample carrier;
a plurality of sample positions arranged on the sample carrier in a first group of sample positions and a second group of sample positions,
wherein the first group of sample positions comprises:
a first row of one or more first sample positions arranged in a first orientation, the first row of one or more first sample positions being an odd-numbered row of sample positions; and
a second row of one or more second sample positions arranged in a second orientation, wherein the second orientation is opposite the first orientation, such that the first row of one or more first sample positions opposes the second row of one or more second sample positions, and such that the first row of one or more first sample positions is spaced apart from the second group of one or more second sample positions by a first row spacing, the second row of one or more second sample positions being an even-numbered row of sample positions;
wherein the second group of sample positions comprises:
a third row of one or more third sample positions arranged in the first orientation, the third row of one or more third sample positions being an odd-numbered row of sample positions; and
a fourth row of one or more fourth sample positions arranged in the second orientation such that the third row of one or more third sample positions opposes the fourth row of one or more fourth sample positions, and such that the third row of one or more third sample positions is spaced apart from the fourth row of one or more fourth sample positions by a second row spacing, the fourth row of one or more fourth sample positions being an even-numbered row of sample positions;
wherein the first group of sample positions and second group of sample positions are spaced such that a gap between the first group of sample positions and second group of sample positions is greater than the first row spacing, and the gap between the first group of sample positions and second group of sample positions is greater than the second row spacing;
a shadow mask comprising a stacked array of hexagonal apertures comprising a series of alternating first sections having decreasing aperture width and second sections having increasing aperture width, wherein the first sections are aligned with odd-numbered rows of sample positions and the second sections are aligned with even-numbered rows of sample positions.
